(19) United States
(12) Patent Application Publication
(10) Pub. No.: US 2022/0190070 A1
(43) Pub. Date: Jun. 16, 2022

(54) DISPLAY DEVICE

(71) Applicant: Samsung Display Co., LTD., Yongin-si (KR)

(72) Inventors: Se Hyun LEE, Hwaseong-si (KR); Hae Chan PARK, Seoul (KR); Won Jun LEE, Seoul (KR)

(21) Appl. No.: 17/507,601

(22) Filed: Oct. 21, 2021

(30) Foreign Application Priority Data
Dec. 11, 2020 (KR) 10-2020-0173606

(51) Int. Cl. H01L 27/32

(52) U.S. Cl. CPC H01L 27/3246

(57) ABSTRACT

A display device includes: a plurality of first banks extended in a first direction on a first substrate and spaced apart from one another; a first electrode and a second electrode extended in the first direction and located on different ones of the first banks so as to be spaced apart from one another; a first insulating layer covering the first electrode, the second electrode, and the plurality of first banks; a plurality of first patterns extended in a second direction crossing the first direction on the first insulating layer and spaced apart from one another; and a plurality of light-emitting elements between adjacent ones of the first patterns, and opposite ends of the light-emitting elements are arranged on the first electrode and the second electrode, respectively, on the first insulating layer, and a height of the first patterns is greater than a diameter of the light-emitting elements.

### CROSS-REFERENCE TO RELATED APPLICATION

This application claims priority to and the benefit of Korean Patent Application No. 10-2020-0173606, filed on Dec. 11, 2020 in the Korean Intellectual Property Office, the entire disclosure of which is incorporated herein by reference.

### BACKGROUND

### 1. Field

Aspects of embodiments of the present disclosure relate to a display device.

### 2. Description of the Related Art

Display devices become more and more important as multimedia technology evolves. Accordingly, a variety of types of display devices, such as organic light-emitting display (OLED) devices and liquid-crystal display (LCD) devices, are currently used.

Display devices include a display panel, such as an organic light-emitting display panel and a liquid-crystal display panel, for displaying images. Among them, a light-emitting display panel may include light-emitting elements. For example, light-emitting diodes (LEDs) may include an organic light-emitting diode (OLED) using an organic material as a light-emitting material, and an inorganic light-emitting diode using an inorganic material as a light-emitting material.

### SUMMARY

According to an aspect of one or more embodiments of the present disclosure, a display device that can improve the alignment of light-emitting elements on electrodes is provided.

It should be noted that aspects and objects of the present disclosure are not limited to the above-mentioned aspect; and other aspects and objects of the present disclosure will be apparent to those skilled in the art from the following descriptions.

According to one or more embodiments of the present disclosure, a display device includes a plurality of patterns disposed between banks on which electrodes are disposed. The plurality of patterns may be spaced apart from each other and arranged in a direction in which the electrodes and the banks are extended, to create level differences in the area between the banks. The patterns can provide areas therebetween in which the light-emitting elements can be disposed, similarly to the banks. Accordingly, the light-emitting elements can be guided such that they are disposed between the patterns where the intensity of electric field is relatively large during the process of fabricating a display device.

In this manner, it is possible to reduce the number of light-emitting elements that are disposed in areas other than the areas between the banks and are not connected to the electrodes but are lost during the process of fabricating the display device. In addition, both ends of the light-emitting elements disposed between the patterns can be properly placed on the electrodes, thereby improving the alignment of the light-emitting elements.

It should be noted that aspects and effects of the present disclosure are not limited to those described above and other aspects and effects of the present disclosure will be apparent to those skilled in the art from the following descriptions.

According to one or more embodiments of the present disclosure, a display device comprises: a plurality of first banks extended in a first direction on a first substrate and spaced apart from one another; a first electrode and a second electrode extended in the first direction and located on different ones of the first banks so as to be spaced apart from one another; a first insulating layer covering the first electrode, the second electrode, and the plurality of first banks; a plurality of first patterns extended in a second direction crossing the first direction on the first insulating layer and spaced apart from one another; and a plurality of light-emitting elements between adjacent ones of the first patterns, wherein opposite ends of the light-emitting elements are arranged on the first electrode and the second electrode, respectively, on the first insulating layer, wherein a height of the first patterns is greater than a diameter of the light-emitting elements.

In an embodiment, the first patterns overlap the first banks and intersect the first banks perpendicularly.

In an embodiment, one light-emitting element of the plurality of light-emitting elements is arranged between every two of the first patterns, and wherein a longitudinal direction of the light-emitting element is parallel to a direction in which the first patterns are extended.

In an embodiment, a pitch of the first patterns is greater than a distance between the first patterns.

In an embodiment, the distance between the first patterns is greater than 0.5 μm and less than 4 μm.

In an embodiment, a width of the first patterns is greater than 1 μm and less than 4.5 μm.

In an embodiment, a cross-section of the first patterns is any of a trapezoid, a square, and a rectangle.

In an embodiment, the display device further comprises a second bank surrounding the plurality of light-emitting elements, the first electrode, the second electrode, and the plurality of first banks, and defining an emission area.

In an embodiment, the first patterns do not overlap with the second bank.

In an embodiment, a height of the first patterns is greater than 0.5 μm and less than a height of the second bank.

In an embodiment, the first patterns comprise a first sub-pattern and a second sub-pattern that are extended in the second direction and spaced apart from each other in the first direction.

In an embodiment, a distance between the first sub-pattern and the second sub-pattern is smaller than the diameter of the light-emitting elements.

In an embodiment, the first patterns are located between the plurality of first banks and do not overlap with the plurality of first banks.

In an embodiment, the display device further comprises a first contact electrode on the first electrode and in contact with a first end of each of the light-emitting elements, and a second contact electrode on the second electrode and in contact with a second end of each of the light-emitting elements.

According to one or more embodiments of the present disclosure, a display device comprises: a plurality of first banks extended in a first direction on a first substrate and spaced apart from one another; a first electrode and a second electrode extended in the first direction and located on different ones of the first banks so as to be spaced apart from one another; a first insulating layer covering the first electrode, the second electrode, and the plurality of first banks; a plurality of first patterns extended in a second direction crossing the first direction on the first insulating layer and spaced apart from one another; and a plurality of light-emitting elements between adjacent ones of the first patterns, wherein opposite ends of the light-emitting elements are arranged on the first electrode and the second electrode, respectively, on the first insulating layer, wherein a width of the first patterns is greater than a diameter of the light-emitting elements and less than a pitch of the first patterns.

In an embodiment, a width of the first patterns is greater than 1 μm and less than 4.5 μm.

In an embodiment, a pitch of the first patterns is greater than a distance between the first patterns and less than 5 μm.

In an embodiment, the display device further comprises a second bank surrounding the plurality of light-emitting elements, the first electrode, the second electrode, and the plurality of first banks, and defining an emission area, wherein the first patterns do not overlap with the second bank.

In an embodiment, the first patterns comprise a first sub-pattern and a second sub-pattern that are extended in the second direction and spaced apart from each other in the first direction.

In an embodiment, the first patterns are located between the plurality of first banks and do not overlap with the plurality of first banks.

### BRIEF DESCRIPTION OF THE DRAWINGS

The above and other aspects and features of the present disclosure will become more apparent by describing in further detail some embodiments thereof with reference to the attached drawings, in which:

FIG. 1 is a plan view showing a display device according to an embodiment of the present disclosure.

FIG. 2 is a plan view showing a pixel of a display device according to an embodiment of the present disclosure.

FIG. 3 is a cross-sectional view taken along the lines Q1-Q1′, Q2-Q2′, and Q3-Q3′ of FIG. 2.

FIG. 4 is a cross-sectional view taken along the line Q4-Q4′ of FIG. 2.

FIG. 5 is a cross-sectional view taken along the line Q5-Q5′ of FIG. 2.

FIG. 6 is an enlarged view showing a region “A” of FIG. 5.

FIG. 7 is a perspective view showing first patterns according to an embodiment of the present disclosure.

FIG. 8 is a view showing a light-emitting element according to an embodiment of the present disclosure.

FIG. 9 is a cross-sectional view of a portion of a display device according to an embodiment of the present disclosure.

FIG. 10 is a plan view showing a pixel of a display device according to an embodiment of the present disclosure.

FIG. 11 is a cross-sectional view taken along the line Q6-Q6′ of FIG. 10.

FIG. 12 is an enlarged view of a region “B” of FIG. 11.

FIG. 13 is a plan view showing a pixel of a display device according to an embodiment of the present disclosure.

FIG. 14 is a cross-sectional view taken along the line Q7-Q7′ of FIG. 13.

FIG. 15 is a view showing first patterns and a light-emitting element of FIG. 13.

FIGS. 16 to 22 are cross-sectional views showing some processing steps of fabricating a display device according to an embodiment of the present disclosure.

FIG. 23 is a view schematically showing a distribution of intensity of an electric field.

FIG. 24 is a graph showing the absolute value of the intensity of the electric field.

FIGS. 25 and 26 are cross-sectional views showing some processing steps of fabricating a display device according to an embodiment of the present disclosure.

FIG. 27 is a plan view showing a sub-pixel of a display device according to an embodiment of the present disclosure.

FIG. 28 is a cross-sectional view taken along the line Q8-Q8′ of FIG. 27.

### DETAILED DESCRIPTION

The present invention will now be described more fully herein with reference to the accompanying drawings, in which some embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole. Each embodiment may be implemented independently of each other or may be implemented together in an association.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the figures. It is to be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (e.g., rotated 90 degrees or at other orientations), and the spatially relative descriptors used herein should be interpreted accordingly.

Unless otherwise defined, all terms (including technical and scientific terms) used herein have the same meaning as commonly understood by one of ordinary skill in the art to which the present disclosure belongs. It is to be further understood that terms, such as those defined in commonly used dictionaries, should be interpreted as having a meaning that is consistent with their meaning in the context of the relevant art and/or the present disclosure, and should not be interpreted in an idealized or overly formal sense, unless expressly so defined herein.

Herein, some embodiments of the present disclosure will be described with reference to the accompanying drawings.

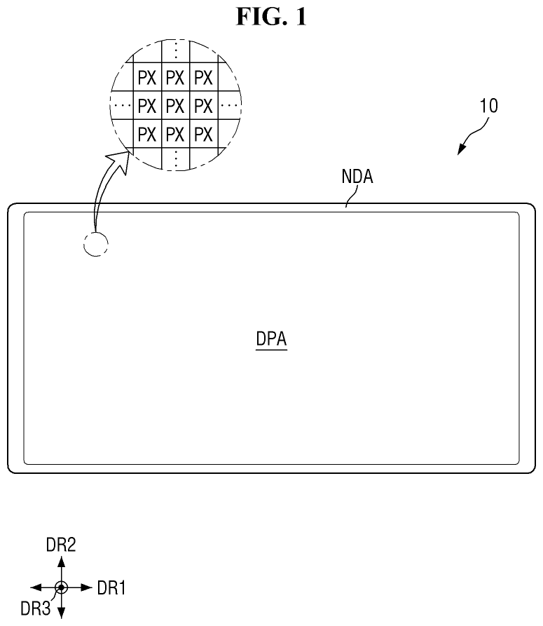

FIG. 1 is a plan view showing a display device according to an embodiment of the present disclosure.

Referring to FIG. 1, a display device 10 may display a moving image or a still image. The display device 10 may refer to any electronic device that provides a display screen. For example, the display device 10 may include a television set, a laptop computer, a monitor, an electronic billboard, an Internet of Things device, a mobile phone, a smartphone, a tablet personal computer (PC), an electronic watch, a smart watch, a watch phone, a head-mounted display device, a mobile communications terminal, an electronic notebook, an electronic book, a portable multimedia player (PMP), a navigation device, a game console, a digital camera, a camcorder, etc.

The display device 10 may include a display panel for providing a display screen. Examples of the display panel may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an example of the display panel 10, but the present disclosure is not limited thereto. Any other display panel may be employed as long as the technical idea of the present disclosure can be equally applied.

The shape of the display device 10 may be modified in a variety of ways. For example, the display device 10 may have any of shapes such as a rectangle with longer lateral sides, a rectangle with longer vertical sides, a square, a quadrangle with rounded corners (vertices), other polygons, a circle, etc. The shape of a display area DPA of the display device 10 may also be similar to the overall shape of the display device 10. FIG. 1 shows the display device 10 and the display area DPA having the shape of a rectangle with longer horizontal sides.

The display device 10 may include the display area DPA and a non-display area NDA. In the display area DPA, images can be displayed. In the non-display area NDA, images are not displayed. The display area DPA may be referred to as an active area, while the non-display area NDA may also be referred to as an inactive area. In an embodiment, the display area DPA may generally occupy the majority of the center of the display device 10.

The display area DPA may include a plurality of pixels PX. The plurality of pixels PX may be arranged in a matrix. The shape of each pixel PX may be, but is not limited to, a rectangle or a square when viewed from the top. In an embodiment, each pixel may have a diamond shape having sides inclined with respect to a direction. In an embodiment, the pixels PX may be arranged in stripes or a PenTile pattern alternately. Each of the pixels PX may include at least one light-emitting element 30 that emits light of a particular wavelength band to represent a color.

The non-display area NDA may be disposed around the display area DPA. The non-display area NDA may surround the display area DPA entirely or partially. In an embodiment, the display area DPA may have a rectangular shape, and the non-display area NDA may be disposed to be adjacent to the four sides of the display area DPA. The non-display area NDA may form a bezel of the display device 10. Lines or circuit drivers included in the display device 10 may be disposed in the non-display area NDA, or external devices may be mounted.

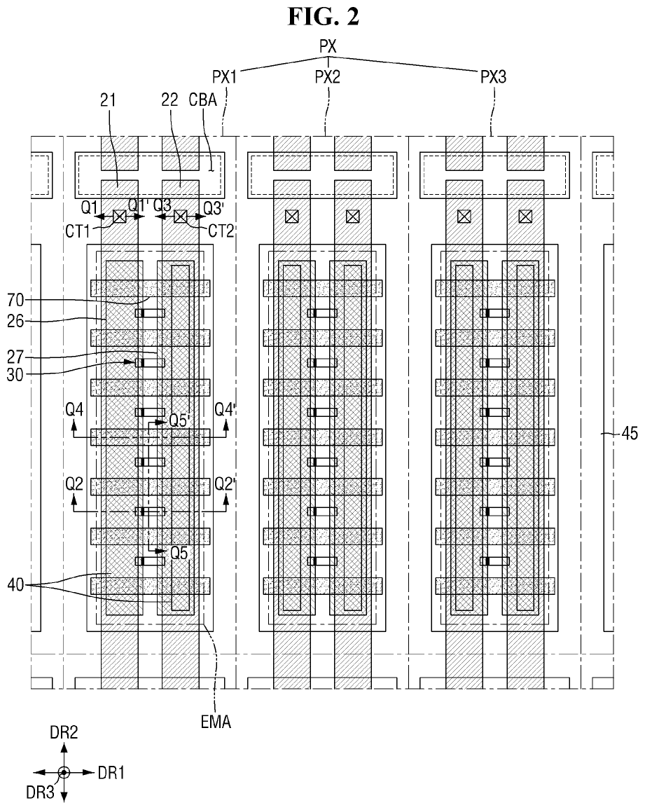

FIG. 2 is a plan view showing a pixel of a display device according to an embodiment of the present disclosure.

Referring to FIG. 2, in an embodiment, each of the plurality of pixels PX may include a plurality of sub-pixels PXn, where n is an integer between one and three. For example, a pixel PX may include a first sub-pixel PX1, a second sub-pixel PX2 and a third sub-pixel PX3. The first sub-pixel PX1 may emit light of a first color, the second sub-pixel PX2 may emit light of a second color, and the third sub-pixel PX3 may emit light of a third color. In an embodiment, the first color may be blue, the second color may be green, and the third color may be red. It is, however, to be understood that the present disclosure is not limited thereto. All the sub-pixels PXn may emit light of the same color. Although the pixel PX includes three sub-pixels PXn in the example shown in FIG. 2, the present disclosure is not limited thereto. The pixel PX may include more than two sub-pixels PXn.

Each of the sub-pixels PXn of the display device 10 may include an emission area EMA and a non-emission area (not shown). In the emission area EMA, the light-emitting elements 30 may be disposed to emit light of a particular wavelength. In the non-emission area, no light-emitting element 30 is disposed and light emitted from the light-emitting elements 30 does not reach and, thus, no light exits therefrom. The emission area may include an area in which the light-emitting elements 30 are disposed, and may include an area adjacent to the light-emitting elements 30 where light emitted from the light-emitting element 30 exits.

It is, however, to be understood that the present disclosure is not limited thereto. The emission area may also include an area in which light emitted from the light-emitting elements 30 is reflected or refracted by other elements to exit. The plurality of light-emitting elements 30 may be disposed in each of the sub-pixels PXn, and the emission area may include the area where the light-emitting elements are disposed and the adjacent area.

Each of the sub-pixels PXn may further include a cut area CBA disposed in the non-emission area. The cut area CBA may be disposed on a side of the emission area EMA in a second direction DR2. The cut area CBA may be disposed between the emission areas EMA of neighboring sub-pixels PXn in the second direction DR2. In the display area DPA of the display device 10, a plurality of emission areas EMA and cut areas CBA may be arranged. For example, the plurality of emission areas EMA and the cut areas CBA may be arranged repeatedly in a first direction DR1, and may be arranged alternately in the second direction DR2. In addition, a spacing between the cut areas CBA in the first direction DR1 may be smaller than a spacing between the emission areas EMA in the first direction DR1. A second bank 45 may be disposed between the cut areas CBA and the emission areas EMA, and a distance therebetween may vary depending on the width of the second bank 45. Although the light-emitting elements 30 are not disposed in the cut areas CBA and, thus, no light exits therefrom, parts of electrodes 21 and 22 disposed in each of the sub-pixels PXn may be disposed there. The electrodes 21 and 22 disposed for each of the sub-pixels PXn may be disposed separately from each other in the cut area CBA.

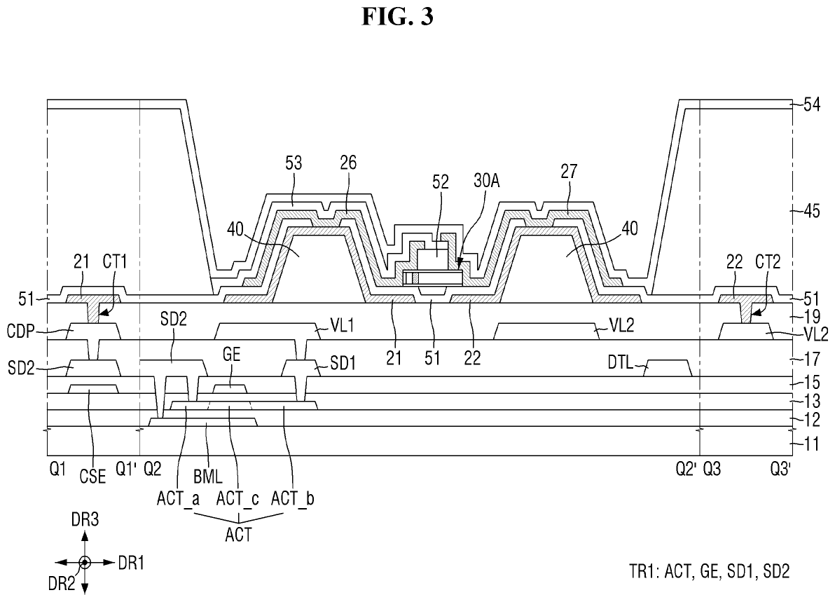

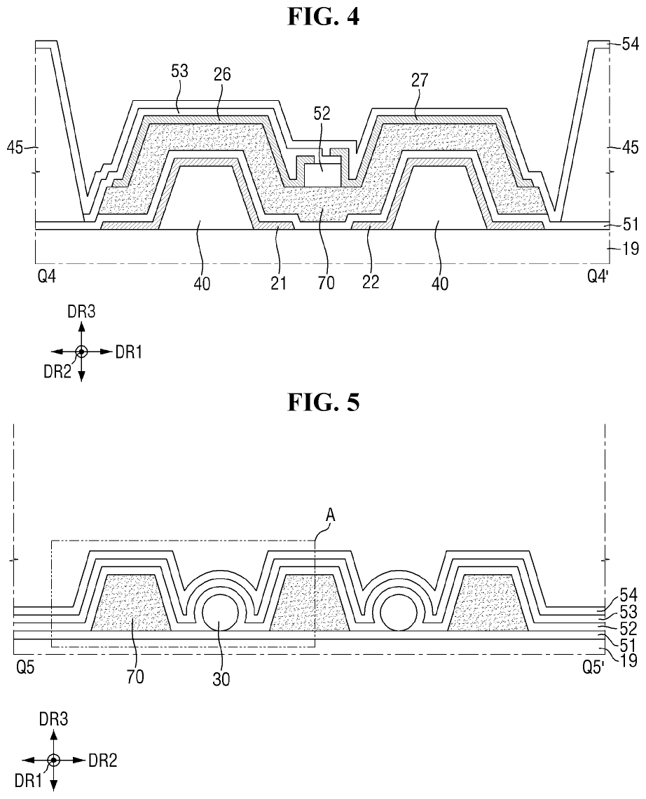

FIG. 3 is a cross-sectional view taken along the lines Q1-Q1′, Q2-Q2′, and Q3-Q3′ of FIG. 2. FIG. 4 is a cross-sectional view taken along the line Q4-Q4′ of FIG. 2.

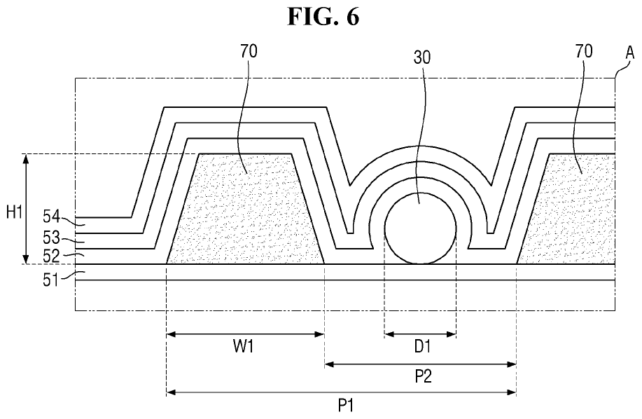

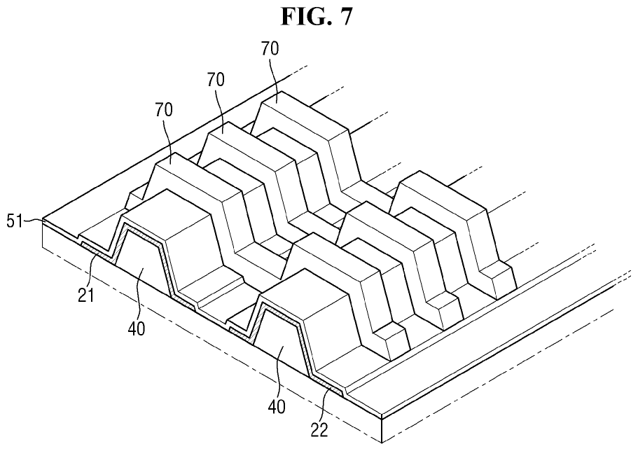

FIG. 5 is a cross-sectional view taken along the line Q5-Q5′ of FIG. 2. FIG. 6 is an enlarged view showing a region “A” of FIG. 5. FIG. 7 is a perspective view showing first patterns according to an embodiment of the present disclosure.

Although FIG. 3 shows only a cross-section of the first sub-pixel PX1 of FIG. 2, the description may be equally applied to the other pixels PX or sub-pixels PXn. FIG. 3 shows the cross-section passing through a first end to a second end of a light-emitting element 30 disposed in a first sub-pixel PX1. FIG. 4 shows a cross-section passing through a first pattern 70 disposed in a first sub-pixel PX1.

Referring to FIGS. 3 to 5 in conjunction with FIG. 2, the display device 10 may include a first substrate 11, a semiconductor layer disposed on the first substrate 11, a plurality of conductive layers, and a plurality of insulating layers.

The first substrate 11 may be an insulating substrate. The first substrate 11 may be made of an insulating material, such as any of glass, quartz, and a polymer resin. The first substrate 11 may be either a rigid substrate or a flexible substrate that can be bent, folded, or rolled.

A light-blocking layer BML may be disposed on the first substrate 11. The light-blocking layer BML may overlap an active layer ACT of a first transistor T1 of the display device 10. The light-blocking layer BML may include a material that blocks light, and thus can prevent or substantially prevent light from entering the active layer ACT of the first transistor T1. For example, the light-blocking layer BML may be formed of an opaque metal material that blocks light transmission. It is, however, to be understood that the present disclosure is not limited thereto. In some implementations, the light-blocking layer BML may be omitted.

In an embodiment, a buffer layer 12 may be disposed entirely on the first substrate 11, including the light-blocking layer BML. The buffer layer 12 may be formed on the first substrate 11 to protect the first thin-film transistors TR1 of the pixels PX from moisture permeating through the first substrate 11 that is susceptible to moisture permeation, and may also provide a flat surface. In an embodiment, the buffer layer 12 may be formed of a plurality of inorganic layers stacked on one another alternately. For example, the buffer layer 12 may be made up of multiple layers in which inorganic layers including at least one of a silicon oxide (SiOx), a silicon nitride (SiNx), and silicon oxynitride (SiON) are stacked on one another alternately.

The semiconductor layer is disposed on the buffer layer 12. The semiconductor layer may include the active layer ACT of the first transistor TR1. These may be disposed to partially overlap with a gate electrode GE of a first gate conductive layer, etc., which will be described later.

Although only the first transistor TR1 among transistors included in the sub-pixels PXn of the display device 10 is depicted in the drawing, the present disclosure is not limited thereto. The display device 10 may include a larger number of transistors. For example, the display device 10 may include more than one transistor in addition to the first transistor TR1, i.e., two or three transistors, in each of the sub-pixels PXn.

According to an embodiment of the present disclosure, the semiconductor layer may include polycrystalline silicon, monocrystalline silicon, an oxide semiconductor, etc. When the semiconductor layer includes an oxide semiconductor, each active layer ACT may include a plurality of conductive regions ACT_a and ACT_b and a channel region ACT_c therebetween. The oxide semiconductor may be an oxide semiconductor containing indium (In). In some embodiments, the oxide semiconductor may be indium-tin oxide (ITO), indium-zinc oxide (IZO), indium-gallium oxide (IGO), indium-zinc-tin oxide (IZTO), indium-gallium-tin oxide (IGTO), indium-gallium-zinc oxide (IGZO), indium-gallium-zinc-tin oxide (IGZTO), etc.

In other embodiments, the semiconductor layer may include polycrystalline silicon. The polycrystalline silicon may be formed by crystallizing amorphous silicon, and, in such a case, the conductive regions of the active layer ACT may be doped regions doped with impurities.

A first gate insulating layer 13 is disposed on the semiconductor layer and the buffer layer 12. The first gate insulating layer 13 may include a semiconductor layer, and may be disposed on the buffer layer 12. The first gate insulating layer 13 may function as a gate insulator of each of the thin-film transistors. The first gate insulating layer 13 may be formed of an inorganic layer including an inorganic material, such as silicon oxide (SiOx), silicon nitride (SiNx) and silicon oxynitride (SiON), or may be formed of a stack of the materials.

The first gate conductive layer is disposed on the first gate insulating layer 13. The first gate conductive layer may include the gate electrode GE of the first transistor TR1 and a first capacitor electrode CSE of a storage capacitor. The gate electrode GE may be disposed such that it overlaps the channel region ACT_c of the active layer ACT in the thickness direction. The first capacitor electrode CSE may be disposed such that it overlaps a second source/drain electrode SD2 of the first transistor TR1 described later in the thickness direction. In some embodiments, the first capacitor electrode CSE may be connected to and integrated with the gate electrode GE, and the integrated layer may partially include the gate electrode GE and the first capacitor electrode CSE. The first capacitor electrode CSE may be disposed such that it overlaps the second source/drain electrode SD2 in the thickness direction, and the storage capacitor may be formed therebetween.

The first gate conductive layer may be made up of a single layer or multiple layers of molybdenum (Mo), aluminum (Al), chromium (Cr), gold (Au), titanium (Ti), nickel (Ni), neodymium (Nd), copper (Cu), or an alloy thereof. It is, however, to be understood that the present disclosure is not limited thereto.

A first protective layer 15 is disposed on the first gate conductive layer. The first protective layer 15 may be disposed to cover and protect the first gate conductive layer. The first protective layer 15 may be formed of an inorganic layer including an inorganic material, such as any of silicon oxide (SiOx), silicon nitride (SiNx), and silicon oxynitride (SiON), or may be formed of a stack of the materials.

A first data conductive layer is disposed on the first protective layer 15. The first data conductive layer may include the first source/drain electrode SD1 and the second source/drain electrode SD2 of the first transistor TR1, and a data line DTL.

The source/drain electrodes SD1 and SD2 of the first transistor TR1 may be in contact with the doping regions ACT_a and ACT_b of the active layer ACT1, respectively, through contact holes penetrating through a first interlayer dielectric layer 17 and the first gate insulating layer 13. In addition, the second source/drain electrode SD2 of the first transistor TR1 may be electrically connected to the light-blocking layer BML through another contact hole.

The data line DTL may apply a data signal to another transistor (not shown) included in the display device 10. Although not shown in the drawings, the data line DTL may be connected to the source/drain electrodes of another transistor to transfer a signal applied from the data line DTL.

The first data conductive layer may be made up of a single layer or multiple layers of molybdenum (Mo), aluminum (Al), chromium (Cr), gold (Au), titanium (Ti), nickel (Ni), neodymium (Nd), copper (Cu), or an alloy thereof. It is, however, to be understood that the present disclosure is not limited thereto.

The first interlayer dielectric layer 17 is disposed on the first data conductive layer. The first interlayer dielectric layer 17 may serve as an insulating layer between the first data conductive layer and other layers disposed thereon. In addition, the first interlayer dielectric layer 17 may cover and protect the first data conductive layer. The first interlayer dielectric layer 17 may be formed of an inorganic layer including an inorganic material, such as any of silicon oxide (SiOx), silicon nitride (SiNx), and silicon oxynitride (SiON), or may be formed of a stack of the materials.

The second data conductive layer is disposed on the first interlayer dielectric layer 17. The second data conductive layer may include a first voltage line VL1, a second voltage line VL2, and a first conductive pattern CDP. A high-level voltage (or a first supply voltage) may be applied to the first voltage line VL1 to be supplied to the first transistor TR1, and a low-level voltage (or a second supply voltage) may be applied to the second voltage line VL2 to be supplied to the second electrode 22. In addition, an alignment signal for aligning the light-emitting elements 30 during a process of fabricating the display device 10 may be applied to the second voltage line VL2.

The first conductive pattern CDP may be electrically connected to the second source/drain electrode SD2 of the first transistor TR1 through a contact hole formed in the first interlayer dielectric layer 17. The first conductive pattern CDP may also come in contact with the first electrode 21 to be described later. The first transistor TR1 may transfer the first supply voltage applied from the first voltage line VL1 to the first electrode 21 through the first conductive pattern CDP. Although the second data conductive layer includes one second voltage line VL2 and one first voltage line VL1 in the example shown in the drawings, the present disclosure is not limited thereto. The second data conductive layer may include more than one first voltage line VL1 and second voltage line VL2.

The second data conductive layer may be made up of a single layer or multiple layers of molybdenum (Mo), aluminum (Al), chromium (Cr), gold (Au), titanium (Ti), nickel (Ni), neodymium (Nd), copper (Cu), or an alloy thereof. It is, however, to be understood that the present disclosure is not limited thereto.

A first planarization layer 19 is disposed on the second data conductive layer. The first planarization layer 19 may include an organic insulating material, e.g., an organic material, such as polyimide (PI), to provide a flat surface.

On the first planarization layer 19, a plurality of first banks 40, first patterns 70, a plurality of electrodes 21 and 22, light-emitting elements 30, a second bank 45, and a plurality of contact electrodes 26 and 27 are disposed. In addition, a plurality of insulating layers 51, 52, 53, and 54 may be further disposed on the first planarization layer 19.

The plurality of first banks 40 may be disposed directly on the first planarization layer 19. The plurality of first banks 40 may be extended in the second direction DR2 within each of the sub-pixels PXn, and may not be extended to an adjacent sub-pixel PXn in the second direction DR2. The first banks 40 may be disposed in the emission area EMA. In addition, the first banks 40 are spaced apart from each other in the first direction DR1, and may form areas where the light-emitting elements 30 are disposed therebetween. The plurality of first banks 40 may be disposed in each of the sub-pixels PXn to form a linear pattern in the display area DPA of the display device 10. Although two first banks 40 are shown in the drawings, the present disclosure is not limited thereto. More than two first banks 40 may be further disposed depending on the number of the electrodes 21 and 22 to be described below.

The first banks 40 may have a structure that at least partly protrudes from the upper surface of the first planarization layer 19. The protruding portion of each of the banks 40 may have inclined side surfaces, and light emitted from the light-emitting element 30 may proceed toward the inclined side surfaces of each of the banks 40. The electrodes 21 and 22 disposed on the first banks 40 may include a material having a high reflectivity, and the light emitted from the light-emitting element 30 may be reflected off the electrodes 21 and 22 disposed on the side surfaces of the first banks 40, such that the light may exit toward the upper side of the first planarization layer 19. That is, the first banks 40 may provide an area where the light-emitting elements 30 are disposed and may also serve as reflective partition walls that reflect light emitted from the light-emitting elements 30 toward the upper side. The side surfaces of the first banks 40 may be inclined in a linear shape, but the present disclosure is not limited thereto. The first banks 40 may have a semicircle or semi-ellipse shape with a curved outer surface. According to an embodiment of the present disclosure, the first banks 40 may include, but are not limited to, an organic insulating material, such as polyimide (PI).

The electrodes 21 and 22 are disposed on the first banks 40 and the first planarization layer 19. The electrodes 21 and 22 may include the first electrode 21 and the second electrode 22. The electrodes 21 and 22 may be extended in the second direction DR2 and may be spaced apart from each other in the first direction DR1.

The first electrode 21 and the second electrode 22 may be extended in the second direction DR2 in each of the sub-pixels PXn, and may be spaced apart from other electrodes 21 and 22 in the cut area CBA. In some embodiments, the cut area CBA may be disposed between the emission areas EMA of the neighboring sub-pixels PXn in the second direction DR2, and the first electrode 21 and the second electrode 22 may be separated from another first electrode 21 and second electrode 22 disposed in an adjacent sub-pixel PXn in the second direction DR2 in the cut area CBA. It is, however, to be understood that the present disclosure is not limited thereto. Some electrodes 21 and 22 may not be separated for each of the sub-pixels PXn but may be extended and disposed across adjacent sub-pixels PXn in the second direction DR2. In an embodiment, only one of the first electrode 21 and the second electrode 22 may be separated.

The first electrode 21 may be electrically connected to the first transistor TR1 through a first contact hole CT1, and the second electrode 22 may be electrically connected to the second voltage line VL2 through a second contact hole CT2. For example, a portion of the first electrode 21 extended in the first direction DR1 under the second bank 45 may be in contact with the first conductive pattern CDP through the first contact hole CT1 penetrating through the first planarization layer 19. A portion of the second electrode 22 extended in the first direction DR1 under the second bank 45 may be in contact with the second voltage line VL2 through the second contact hole CT2 penetrating through the first planarization layer 19. It is, however, to be understood that the present disclosure is not limited thereto. According to some embodiments of the present disclosure, the first contact hole CT1 and the second contact hole CT2 may be formed in the emission area EMA surrounded by the second bank 45 so as not to overlap the second bank 45.

Although one first electrode 21 and one second electrode 22 is disposed in each sub-pixel PXn in the drawings, the present disclosure is not limited thereto. In some embodiments, a greater number of first electrodes 21 and second electrodes 22 may be disposed in each sub-pixel PXn. In addition, the first electrode 21 and the second electrode 22 disposed in each of the sub-pixels PXn may not necessarily have a shape extended in one direction but may have any of a variety of structures. For example, the first electrode 21 and the second electrode 22 may have a partially curved or bent shape, and one electrode may be disposed to surround the other electrode.

The first electrode 21 and the second electrode 22 may be disposed on the first banks 40, respectively. According to some embodiments of the present disclosure, each of the first electrode 21 and the second electrode 22 may have a larger width than that of the first banks 40. For example, the first electrode 21 and the second electrode 22 may be disposed to cover outer surfaces of the first banks 40. The first electrode 21 and the second electrode 22 may be disposed on side surfaces of the first banks 40, respectively, and a distance between the first electrode 21 and the second electrode 22 may be smaller than a distance between the first banks 40. In an embodiment, at least a portion of the first electrode 21 and the second electrode 22 may be disposed directly on the first planarization layer 19 so as to be located on a same plane.

Each of the electrodes 21 and 22 may include a conductive material having a high reflectance. For example, each of the electrodes 21 and 22 may include a metal such as any of silver (Ag), copper (Cu), and aluminum (Al) as the material having a high reflectance, and may be an alloy including aluminum (Al), nickel (Ni), lanthanum (La), etc. Each of the electrodes 21 and 22 may reflect light that is emitted from the light-emitting element 30 and travels toward the side surfaces of the first banks 40 toward the upper side of each of the sub-pixels PXn.

It is, however, to be understood that the present disclosure is not limited thereto. Each of the electrodes 21 and 22 may further include a transparent conductive material. For example, each of the electrodes 21 and 22 may include a material such as any of indium tin oxide (ITO), indium zinc oxide (IZO), and indium tin zinc oxide (ITZO). In some embodiments, each of the electrodes 21 and 22 may have a structure in which one or more layers of a transparent conductive material and a metal layer having high reflectivity are stacked, or may be made up of a single layer thereof. For example, each of the electrodes 21 and 22 may have a stack structure, such as ITO/silver (Ag)/ITO/, ITO/Ag/IZO, or ITO/Ag/ITZO/IZO.

The electrodes 21 and 22 may be electrically connected to the light-emitting elements 30, and a voltage (e.g., a predetermined voltage) may be applied such that the light-emitting elements 30 can emit light. For example, the plurality of electrodes 21 and 22 may be electrically connected to the light-emitting element 30 through contact electrodes 26 and 27 to be described later, and may transfer electrical signals applied to the electrodes 21 and 22 to the light-emitting element 30 through the contact electrodes 26 and 27.

According to an embodiment of the present disclosure, one of the first electrode 21 and the second electrode 22 may be electrically connected to an anode electrode of the light-emitting element 30, while the other one may be electrically connected to a cathode electrode of the light-emitting element 30. It is, however, to be understood that the present disclosure is not limited thereto.

In addition, the electrodes 21 and 22 may be utilized to form an electric field within the sub-pixel PXn to align the light-emitting elements 30. The light-emitting elements 30 may be disposed between the first electrode 21 and the second electrode 22 by an electric field formed on the first electrode 21 and the second electrode 22. According to an embodiment of the present disclosure, the light-emitting elements 30 of the display device 10 may be sprayed on the electrodes 21 and 22 via an inkjet printing process. When droplets of ink containing the light-emitting elements 30 are ejected onto the electrodes 21 and 22, an alignment signal is applied to the electrodes 21 and 22 to generate an electric field. The light-emitting elements 30 dispersed in the ink may be aligned on the electrodes 21 and 22 by receiving an electrophoretic force by the electric field generated over the electrodes 21 and 22.

The first insulating layer 51 is disposed on the first planarization layer 19. The first insulating layer 51 may be disposed to cover the first banks 40, the first electrode 21, and the second electrode 22 disposed on the first planarization layer 19, such that a portion of an upper surface of each of the first electrode 21 and the second electrode 22 is exposed. In other words, the first insulating layer 51 may be formed substantially entirely on the first planarization layer 19, and may include openings partially exposing the first electrode 21 and the second electrode 22.

In an embodiment, the first insulating layer 51 may have a step such that a portion of an upper surface is recessed between the first electrode 21 and the second electrode 22. As the first insulating layer 51 is disposed to cover the first electrode 21 and the second electrode 22 disposed between the first banks 40, the upper surface thereof may have level differences along the first direction DR1 in which the first electrode 21 and the second electrode 22 are arranged.

The first insulating layer 51 can protect the first electrode 21 and the second electrode 22 and insulate them from each other. In addition, the first insulating layer 51 can prevent or substantially prevent the light-emitting element 30 disposed thereon from being brought into contact with other elements and damaged.

According to an embodiment of the present disclosure, the display device 10 may include a plurality of first patterns 70 disposed between the first banks 40. The plurality of first patterns 70 may be disposed on the first insulating layer 51. In an embodiment, the plurality of first patterns 70 may have a thickness smaller than that of the first banks 40 and may be spaced apart from each other in the second direction DR2. In an embodiment, a width of the first patterns 70 may be greater than the distance between the first banks 40 and may be smaller than a distance between the second banks 45 to be described later. In an embodiment, the first patterns 70 may be spaced apart from the second bank 45. In an embodiment, the first patterns 70 may have a trapezoidal cross-section. The cross-sectional shape of the first patterns 70 may be similar to one obtained by patterning an organic material. It is, however, to be understood that the present disclosure is not limited thereto.

As described above, the first banks 40 may form the areas where the light-emitting elements 30 are disposed therebetween. During the process of fabricating the display device 10, the light-emitting elements 30 disposed in an ink may be ejected onto the electrodes 21 and 22 to be described later, and may be arranged thereon by an electric field generated over the electrodes 21 and 22. The first banks 40 disposed in each of the sub-pixels PXn have a shape protruding from the upper surface of the first planarization layer 19, to distinguish between the inner areas therebetween and the outer areas. Accordingly, the light-emitting elements 30 can be guided such that the light-emitting elements 30 are arranged between the first banks 40.

Similarly, the plurality of first patterns 70 arranged between the first banks 40 may form level differences in the areas where the light-emitting elements 30 are disposed between the first banks 40. The areas between the first banks 30 may be divided into areas where the first patterns 70 are disposed and the areas between the first patterns 70 spaced apart from each other in the second direction DR2. The light-emitting elements 30 may be guided so as to be disposed between the first patterns 70. Accordingly, the light-emitting elements 30 can be disposed in the particular areas between the first banks 40, and both, or opposite, ends of the light-emitting elements 30 can be placed properly on the electrodes 21 and 22, respectively.

In addition, as the first patterns 70 have a certain thickness (e.g., a predetermined thickness), the intensity of an electric field is weak over the first patterns 70 when the electric field is generated in order to align the light-emitting elements 30, which will be described later. As a result, the light-emitting elements 30 can be guided to the areas between the first banks 30 where the intensity of the electric field is relatively large and arranged in those areas. Accordingly, the light-emitting elements 30 can be arranged between the first banks 40, and both ends of the light-emitting elements 30 can be placed properly on the electrodes 21 and 22, respectively. The first patterns 70 will be described in further detail later with reference to other drawings.

The second bank 45 may be disposed on the first insulating layer 51. In an embodiment, the second bank 45 may be disposed in a lattice pattern on the entire surface of the display area DPA including portions extended in the first direction DR1 and the second direction DR2 when viewed from the top. The second bank 45 may be disposed along the border of each of the sub-pixels PXn to distinguish adjacent sub-pixels PXn from one another.

In addition, the second bank 45 may be disposed to surround the emission area EMA and the cut area CBA disposed in each of the sub-pixels PXn to distinguish them. The first electrode 21 and the second electrode 22 may be extended in the second direction DR2 and may be disposed across a portion of the second bank 45 that is extended in the first direction DR1. In an embodiment, the portion of the second bank 45 extended in the second direction DR2 may have a larger width between the emission areas EMA than between the cut areas CBA. Accordingly, a distance between the cut areas CBA may be smaller than a distance between the emission areas EMA.

According to an embodiment of the present disclosure, the second bank 45 may have a height greater than a height of the first banks 40. The second bank 45 can prevent or substantially prevent an ink from overflowing into adjacent sub-pixels PX during an inkjet printing process of the process of fabricating the display device 10. The second bank 45 can separate different sub-pixels PXn from one another such that the ink in which different light-emitting elements 30 are dispersed is not mixed. The second bank 45 may include, but is not limited to, polyimide (PI), like the first bank 40.

The light-emitting elements 30 may be disposed on the first insulating layer 51. The light-emitting elements 30 may be spaced apart from one another in the second direction DR2 in which the electrodes 21 and 22 are extended, and may be aligned substantially parallel to one another. The spacing between the light-emitting elements 30 is not particularly limited. The light-emitting elements 30 may have a shape extended in a direction. The direction in which the electrodes 21 and 22 are extended may be substantially perpendicular to the direction in which the light-emitting elements 30 are extended. It is, however, to be understood that the present disclosure is not limited thereto. For example, the light-emitting elements 30 may be oriented obliquely to the direction in which the electrodes 21 and 22 are extended, rather than being perpendicular to it.

The light-emitting elements 30 may include light-emitting layers 36 including different materials to emit light of different wavelength bands to the outside. The display device 10 may include the light-emitting elements 30 that emit light of different wavelengths. Accordingly, lights of the first color, the second color, and the third color may exit from the first sub-pixel PX1, the second sub-pixel PX2, and the third sub-pixel PX3, respectively. It is, however, to be understood that the present disclosure is not limited thereto. In some implementations, the sub-pixels PXn may include the same kind of light-emitting elements 30 and may emit light of substantially the same color.

The opposite ends of the light-emitting elements 30 may be disposed on the electrodes 21 and 22 between the first banks 40, respectively. For example, a first end of each of the light-emitting elements 30 may be located on the first electrode 21, and a second end thereof may be located on the second electrode 22. In an embodiment, a length of the light-emitting elements 30 may be larger than a distance between the first electrode 21 and the second electrode 22, and the opposite ends of the light-emitting elements 30 may be disposed on the first electrode 21 and the second electrode 22, respectively.

According to an embodiment of the present disclosure, the light-emitting elements 30 may be disposed between adjacent ones of the first patterns 70. For example, the light-emitting elements 30 may be disposed in the areas where the first patterns 70 are not disposed. It is, however, to be understood that the present disclosure is not limited thereto. For example, some of the light-emitting elements 30 may be in contact with the first patterns 70 or may be disposed on the first patterns 70. The first insulating layer 51 may be disposed between the first banks 40 and between the first electrode 21 and the second electrode 22, and the first patterns 70 may be disposed on the first insulating layer 51. The light-emitting elements 30 disposed on the first insulating layer 51 may be disposed on the first insulating layer 51 having a low height between the first patterns 70. In an embodiment, one light-emitting element 30 may be aligned and disposed between the first patterns 70. The longitudinal direction of the aligned light-emitting elements 30 may be arranged in the first direction DR1 and parallel to the direction in which the first patterns 70 are extended.

In an embodiment, the light-emitting elements 30 of the display device 10 may be arranged so as to be extended in parallel to the first planarization layer 19. The semiconductor layers included in the light-emitting elements 30 may be disposed sequentially in the direction parallel to the upper surface of the first planarization layer 19. It is, however, to be understood that the present disclosure is not limited thereto.

In some implementations, when the light-emitting elements 30 have a different structure, a plurality of layers may be disposed in a direction perpendicular to the first planarization layer 19.

The ends of each of the light-emitting elements 30 may be in contact with the contact electrodes 26 and 27, respectively. According to an embodiment of the present disclosure, a portion of the semiconductor layer or the electrode layer of each of the light-emitting elements 30 is exposed because an insulating film 38 is not formed at an end surface on a side of the extending direction, and the exposed portion of the semiconductor layer may be in contact with the contact electrodes 26 and 27. It is, however, to be understood that the present disclosure is not limited thereto. In some implementations, at least a portion of the insulating film 38 of the light-emitting element 30 is removed, such that the side surface of the semiconductor layers of the light-emitting element 30 may be partially exposed. The exposed side surface of the semiconductor layer may be in direct contact with the contact electrodes 26 and 27.

The second insulating layer 52 may be partially disposed on the light-emitting elements 30. For example, the second insulating layer 52 may be disposed to partially surround the outer surfaces of the light-emitting elements 30 such that the ends and the opposite ends of the light-emitting elements 30 are not covered. The contact electrodes 26 and 27 may be in contact with the opposite ends of the light-emitting elements 30 not covered by the second insulating layer 52, which will be described later. The portion of the second insulating layer 52 which is disposed on the light-emitting elements 30 may be extended in the second direction DR2 on the first insulating layer 51 when viewed from the top, thereby forming a linear or island-like pattern in each of the sub-pixels PXn. The second insulating layer 52 can protect the light-emitting elements 30 and fix the light-emitting elements 30 during the process of fabricating the display device 10.

The plurality of contact electrodes 26 and 27 and a third insulating layer 53 may be disposed on the second insulating layer 52.

The plurality of contact electrodes 26 and 27 may have a shape extended in a direction. The first and second contact electrodes 26 and 27 may be disposed on parts of the first electrode 21 and the second electrode 22, respectively. The first contact electrode 26 may be disposed on the first electrode 21, the second contact electrode 27 may be disposed on the second electrode 22, and each of the first contact electrode 26 and the second contact electrode 27 may have a shape extended in the second direction DR2. The first contact electrode 26 and the second contact electrode 27 may be spaced apart from and face each other in the first direction DR1, and may form a stripe pattern inside the emission area EMA of each sub-pixel PXn. The first contact electrode 26 and the second contact electrode 27 are disposed to cover the first patterns 70, so as to be disposed along the level differences formed by the first patterns 70 thereunder between the first banks 40 where the light-emitting elements 30 are disposed.

In some embodiments, widths of the first contact electrode 26 and the second contact electrode 27 measured in a direction may be equal to or smaller than widths of the first electrode 21 and the second electrode 22 measured in the direction, respectively. The first contact electrode 26 and the second contact electrode 27 may be in contact with the ends and the opposite ends of the light-emitting elements 30, respectively, and may cover parts of the upper surfaces of the first electrode 21 and the second electrode 22, respectively.

The contact electrodes 26 and 27 may be in contact with the light-emitting elements 30 and the electrodes 21 and 22, respectively. The semiconductor layer is exposed at the opposite end surfaces of the light-emitting element 30 on the side of the extending direction, and the first contact electrode 26 and the second contact electrode 27 may be in contact with the light-emitting element 30 at the exposed end surfaces where the semiconductor layer is exposed. The first end of each of the light-emitting elements 30 may be electrically connected to the first electrode 21 through the first contact electrode 26, and the second end thereof may be electrically connected to the second electrode 22 through the second contact electrode 27.

Although one first contact electrode 26 and one second contact electrode 27 are disposed in one sub-pixel PXn in the drawings, the present disclosure is not limited thereto. The numbers of the first contact electrodes 26 and the second contact electrodes 27 may vary depending on the numbers of the first electrodes 21 and the second electrodes 22 disposed in each of the sub-pixels PXn.

The third insulating layer 53 is disposed on the first contact electrode 26. The third insulating layer 53 may electrically insulate the first contact electrode 26 from the second contact electrode 27. The third insulating layer 53 is disposed to cover the first contact electrode 26 and may not be disposed on the second end of the light-emitting elements 30 such that the light-emitting elements 30 come in contact with the second contact electrode 27. The third insulating layer 53 may be in contact with a portion of each of the first contact electrode 26 and the second insulating layer 52 on the upper surface of the second insulating layer 52. A side surface of the third insulating layer 53 on a side where the second electrode 22 is disposed may be aligned with a side surface of the second insulating layer 52. In addition, the third insulating layer 53 may also be disposed in the non-emission area, for example, on the first insulating layer 51 disposed on the first planarization layer 19. It is, however, to be understood that the present disclosure is not limited thereto.

The second contact electrode 27 is disposed on the second electrode 22, the second insulating layer 52 and the third insulating layer 53. The second contact electrode 27 may be in contact with the second ends of the light-emitting elements 30 and the exposed upper surface of the second electrode 22. The second ends of the light-emitting elements 30 may be electrically connected to the second electrode 22 through the second contact electrode 27.

The second contact electrode 27 may be partially in contact with the second insulating layer 52, the third insulating layer 53, the second electrode 22, and the light-emitting elements 30. The first contact electrode 26 and the second contact electrode 27 may not be in contact with each other by the second insulating layer 52 and the third insulating layer 53. It is, however, to be understood that the present disclosure is not limited thereto. In some implementations, the third insulating layer 53 may be omitted.

The contact electrodes 26 and 27 may include a conductive material. For example, the contact electrodes may include any of ITO, IZO, ITZO, aluminum (Al), etc. For example, the contact electrodes 26 and 27 may include a transparent conductive material, and light emitted from the light-emitting elements 30 may transmit the contact electrodes 26 and 27 to proceed toward the electrodes 21 and 22. It is, however, to be understood that the present disclosure is not limited thereto.

In an embodiment, the fourth insulating layer 54 may be disposed entirely on the first substrate 11. The fourth insulating layer 54 may serve to protect the elements disposed on the first substrate 11 against an external environment.

Each of the above-described first insulating layer 51, second insulating layer 52, third insulating layer 53, and fourth insulating layer 54 may include an inorganic insulating material or an organic insulating material. According to an embodiment of the present disclosure, the first insulating layer 51, the second insulating layer 52, the third insulating layer 53, and the fourth insulating layer 54 may include an inorganic insulating material, such as any of silicon oxide (SiOx), silicon nitride (SiNx), silicon oxynitride (SiOxNy), aluminum oxide (Al₂O₃) and aluminum nitride (AlN). In an embodiment, the first insulating layer 51, the second insulating layer 52, the third insulating layer 53, and the fourth insulating layer 54 may include, as an organic insulating material, an acrylic resin, an epoxy resin, a phenol resin, a polyamide resin, a polyimide resin, an unsaturated polyester resin, a polyphenylene resin, a polyphenylene sulfide resin, benzocyclobutene, a cardo resin, a siloxane resin, a silsesquioxane resin, polymethyl methacrylate, polycarbonate, a polymethyl methacrylate-polycarbonate synthetic resin, etc. It is, however, to be understood that the present disclosure is not limited thereto.

Referring to FIGS. 4 to 7, the first patterns 70 according to an embodiment are spaced apart from each other in the second direction DR2 between the second banks 45. During the process of fabricating the display device 10, after forming the first insulating layer 51 and the second banks 45, a process of ejecting an ink containing the light-emitting elements 30 onto each sub-pixel PXn is carried out. The light-emitting elements 30 dispersed in the ink are ejected onto the electrodes 21 and 22, and the opposite ends of the light-emitting elements 30 are placed on the electrodes 21 and 22, respectively, while positions and orientations of the light-emitting elements 30 are changed by the electric field formed over the electrodes 21 and 22.

The light-emitting elements 30 dispersed in the ink may be randomly positioned within the emission area EMA surrounded by the second bank 45 and may be seated in areas other than between the first banks 40 as well. The opposite ends of the light-emitting elements 30 seated in areas other than between the first banks 40 may not be electrically connected to the electrodes 21 and 22 but may be lost during the fabricating process. When a substantial amount of the light-emitting elements 30 are lost, it is necessary to eject a large amount of ink in order to meet the number of light-emitting elements 30 required for each sub-pixel PXn. As a result, the process yield may be lowered.

As the first bank 40 has a shape protruding from the first planarization layer 19, it can distinguish the emission areas EMA from position to position, and can guide the light-emitting elements 30 such that a large number of light-emitting elements 30 are located in the space formed by the first banks 40. Similarly, the first patterns 70 are formed so as to protrude from the upper surface of the first insulating layer 51 to distinguish the areas between the second banks 45 from position to position. The areas where the first patterns 70 are disposed may be a higher position, and the light-emitting elements 30 dispersed in the ink can be guided toward the space between the first patterns 70 when their positions are changed by the electric field. For example, as shown in FIG. 5, the first patterns 70 may be disposed higher than the first insulating layer 51 with respect to the upper surface of the first insulating layer 51, and the areas where the first patterns 70 are not disposed, i.e., the areas between the first patterns 70 may be lower than the areas where the first patterns 70 are disposed. Most of the light-emitting elements 30 dispersed in the ink may be guided to be seated on the first insulating layer 51 at a lower position. In particular, when the light-emitting elements 30 are placed on the first patterns 70, the light-emitting element 30 may be moved to the areas between the first patterns 70 from the areas on the first patterns 70 and aligned therein because the intensity of the electric field is greater in the areas between the first patterns 70.

According to an embodiment of the present disclosure, the first patterns 70 may guide the light-emitting elements 30 so as to be located at intended positions in the emission area EMA of each sub-pixel PXn, similar to the first banks 40, such that a large number of light-emitting elements 30 can be disposed between the first banks 40. Accordingly, a number of light-emitting elements 30 lost during the process of fabricating the display device 10 can be reduced, and both ends of the light-emitting elements 30 can be placed on the electrodes 21 and 22, respectively, between the first banks 40, such that it is possible to prevent a contact failure between the contact electrodes 26 and 27 and the light-emitting elements 30.

The first patterns 70 may have a thickness sufficient to guide the light-emitting elements 30 so as to be disposed between the first patterns 70 by the level differences. According to an embodiment of the present disclosure, a height H1 of the first patterns 70 may be larger than a diameter D1 of the light-emitting elements 30. As the height H1 of the first patterns 70 is greater than the diameter D1 of the light-emitting elements 30, the intensity of the electric field generated over the first patterns 70 may become larger than that over the first insulating layer 51 where the light-emitting elements 30 are seated between the first patterns 70. As a result, the light-emitting elements 30 may be moved to the side where the intensity of the electric field is greater, and thus may be aligned between the electrodes 21 and 22. According to an embodiment of the present disclosure, the height H1 of the first patterns 70 may be larger than the diameter D1 of the light-emitting elements 30, for example, larger than 0.5 μm. In addition, the height H1 of the first patterns 70 may be smaller than the height of the second bank 45. The ink may be ejected onto the first patterns 70 to evenly spread in the area partitioned by the second bank 45. Since the height H1 of the first patterns 70 is smaller than that of the second bank 45, the light-emitting elements can be spread evenly.

In addition, a pitch P1 of the first patterns 70 may be larger than a distance P2 between the first patterns 70. The pitch P1 of the first patterns 70 is a distance including the distance P2 between the first patterns 70 and may be larger than the distance P2 between the first patterns 70. In an embodiment, the pitch P1 of the first patterns 70 may be equal to or less than 5 μm. The light-emitting elements 30 may be aligned such that they are spaced apart from one another by a certain distance by a repulsive force acting on each other. In an embodiment, the distance between the light-emitting elements 30 spaced apart from one another due to the repulsive force may be approximately 5 μm. When the pitch P1 of the first patterns 70 is greater than 5 μm, it is possible to prevent a number of light-emitting elements 30 disposed between the first patterns 70 from sticking together and creating a short circuit. According to an embodiment of the present disclosure, the distance P2 between the first patterns 70 may be greater than 0.5 μm and less than 4 μm.

In addition, according to an embodiment of the present disclosure, a width W1 of the first patterns 70 may be greater than the diameter D1 of the light-emitting elements 30 and may be smaller than the pitch P1 of the first patterns 70. The width W1 of the first patterns 70 may be adjusted within the pitch P1 of the first patterns 70. The pitch P1 of the first patterns 70 may be within the above-described range such that one light-emitting element 30 can be aligned between the first patterns 70. The distance P2 between the first patterns 70 and the width W1 of the first patterns 70 may be included in the pitch P1 of the first patterns 70. Accordingly, if the width W1 of the first patterns 70 increases, the distance P2 between the first patterns 70 may decrease, and vice versa. According to an embodiment of the present disclosure, since the pitch P1 of the first patterns 70 is less than 5 μm and the distance P2 between the first patterns 70 is greater than 0.5 μm and less than 4 μm, the width W1 of the first patterns 70 may be greater than 1 μm and less than 4.5 μm. When the width W1 of the first patterns 70 is greater than 1 μm, the light-emitting elements 30 can be rotated and aligned within the distance P2 between the first patterns 70, and, when the width W1 of the first patterns 70 is less than 4.5 μm, the light-emitting elements 30 may be well seated within the distance P2 between the first patterns 70.

It is to be noted that the width W1 and the height H1 of the first patterns 70 are not limited to those described above, and may be adjusted as the diameter D1 and/or the length of the light-emitting elements 30 is changed.

According to an embodiment of the present disclosure, the display device 10 may include a plurality of first patterns 70 arranged in a direction between the second banks 45. The display device 10 can guide the light-emitting elements 30 such that most of the light-emitting elements 30 are aligned at intended positions during the fabricating process, and can reduce the number of the light-emitting elements 30 lost in each sub-pixel PXn.

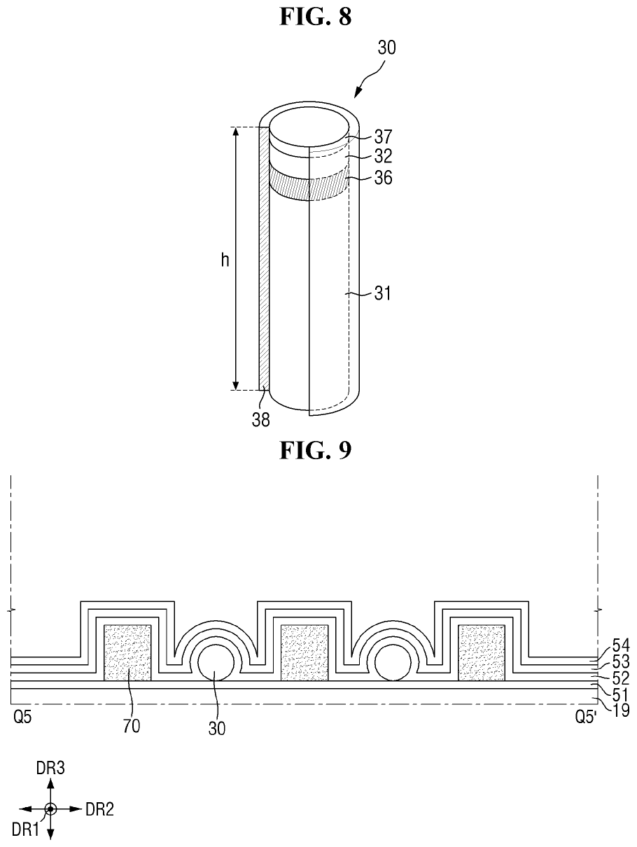

FIG. 8 is a view showing a light-emitting element according to an embodiment of the present disclosure.

The light-emitting element 30 may be a light-emitting diode. In an embodiment, the light-emitting element 30 may have a size in micrometers or nanometers and may be an inorganic light-emitting diode made of an inorganic material. Inorganic light-emitting diodes may be aligned between two electrodes facing each other as polarities are created by forming an electric field in a particular direction between the two electrodes. The light-emitting elements 30 may be aligned between two electrodes by an electric field formed over the two electrodes.

The light-emitting element 30 according to an embodiment may have a shape extended in a first direction. The light-emitting element 30 may have a shape of a rod, wire, tube, etc. In an embodiment, the light-emitting element 30 may have a cylindrical or rod-like shape. However, it is to be understood that the shape of the light-emitting element 30 is not limited thereto. The light-emitting element 30 may have any of a variety of shapes, including a polygonal column shape such as a cube, a cuboid, and a hexagonal column, or a shape that is extended in a direction with partially inclined outer surfaces. The plurality of semiconductors included in the light-emitting element 30 to be described later may have a structure sequentially arranged or stacked along the first direction.

The light-emitting element 30 may include a semiconductor layer doped with impurities of a conductive type (e.g., p-type or n-type). The semiconductor layers may emit light of a certain wavelength band by transmitting an electric signal applied from an external power source.

As shown in FIG. 8, the light-emitting element 30 may include a first semiconductor layer 31, a second semiconductor layer 32, the light-emitting layer 36, an electrode layer 37 and the insulating film 38.

In an embodiment, the first semiconductor layer 31 may be an n-type semiconductor. For example, when the light-emitting element 30 emits light of a blue wavelength band, the first semiconductor layer 31 may include a semiconductor material having the following chemical formula: AlₓGa_{y}In_{1-x-y}N (0≤x≤1, 0≤y≤1, 0≤x+y≤1). For example, the first semiconductor layer 31 may be at least one of n-type doped AlGaInN, GaN, AlGaN, InGaN, AlN, and InN. The first semiconductor layer 31 may be doped with an n-type dopant, and the n-type dopant may be Si, Ge, Sn, etc., for example. According to an embodiment of the present disclosure, the first semiconductor layer 31 may be n-GaN doped with n-type Si. The length of the first semiconductor layer 31 may be in a range, but is not limited to, from 1.5 μm to 5 μm.

The second semiconductor layer 32 is disposed on the light-emitting layer 36 to be described later. In an embodiment, the second semiconductor layer 32 may be a p-type semiconductor. For example, when the light-emitting element 30 emits light of a blue or green wavelength band, the second semiconductor layer 32 may include a semiconductor material having the following chemical formula: AlₓGa_{y}In_{1-x-y}N (0≤x≤1, 0≤y≤1, 0≤x+y≤1). For example, the second semiconductor layer 32 may be at least one of p-type doped AlGaInN, GaN, AlGaN, InGaN, AlN, and InN. The second semiconductor layer 32 may be doped with a p-type dopant, and the p-type dopant may be Mg, Zn, Ca, Se, Ba, etc., for example. According to an embodiment of the present disclosure, the second semiconductor layer 32 may be p-GaN doped with p-type Mg. The length of the second semiconductor layer 32 may be in a range, but is not limited to, from 0.05 μm to 0.10 μm.

Although each of the first semiconductor layer 31 and the second semiconductor layer 32 is implemented as a signal layer in the drawings, the present disclosure is not limited thereto. According to some embodiments of the present disclosure, depending on the material of the light-emitting layer 36, the first semiconductor layer 31 and the second semiconductor layer 32 may further include a larger number of layers, e.g., a clad layer or a tensile strain barrier reducing (TSBR) layer.

The light-emitting layer 36 is disposed between the first semiconductor layer 31 and the second semiconductor layer 32. The light-emitting layer 36 may include a material having a single or multiple quantum well structure. When the light-emitting layer 36 includes a material having the multiple quantum well structure, the structure may include quantum layers and well layers alternately stacked on one another. The light-emitting layer 36 may emit light as electron-hole pairs are combined therein in response to an electrical signal applied through the first semiconductor layer 31 and the second semiconductor layer 32. For example, when the light-emitting layer 36 emits light of the blue wavelength band, the light-emitting layer 36 may include a material such as AlGaN and AlGaInN. In an embodiment, when the light-emitting layer 36 has a multi-quantum well structure in which quantum layers and well layers are alternately stacked on one another, the quantum layers may include AlGaN or AlGaInN, and the well layers may include a material such as GaN and AlGaN. In an embodiment, the light-emitting layer 36 includes AlGaInN as the quantum layer and AlInN as the well layer, and, as described above, the light-emitting layer 36 may emit blue light having a center wavelength band of 450 nm to 495 nm.

It is, however, to be understood that the present disclosure is not limited thereto. The light-emitting layer 36 may have a structure in which a semiconductor material having a large band gap energy and a semiconductor material having a small band gap energy are alternately stacked on one another, and may include other Group III to Group V semiconductor materials depending on the wavelength range of the emitted light. Accordingly, the light emitted from the light-emitting layer 36 is not limited to the light of the blue wavelength band. The light-emitting layer 36 may emit light of red or green wavelength band in some implementations. The length of the light-emitting layer 36 may be, but is not limited to, in the range of 0.05 μm to 0.10 μm.

The light emitted from the light-emitting layer 36 may exit not only through the outer surfaces of the light-emitting element 30 in the longitudinal direction but also through the side surfaces. The direction in which the light emitted from the light-emitting layer 36 propagates is not limited to one direction.

The electrode layer 37 may be an ohmic contact electrode. It is, however, to be understood that the present disclosure is not limited thereto. The electrode layer 37 may be a Schottky contact electrode. The light-emitting element 30 may include at least one electrode layer 37. Although the light-emitting element 30 includes one electrode layer 37 in the example shown in FIG. 8, the present disclosure is not limited thereto. In some implementations, the light-emitting element 30 may include a larger number of electrode layers 37 or the electrode layer may be omitted. The following description of the light-emitting element 30 may be equally applied even if the number of electrode layers 37 is different or it further includes other structures.

The electrode layer 37 can reduce the resistance between the light-emitting element 30 and the electrodes or the contact electrodes when the light-emitting element 30 is electrically connected to the electrodes or the contact electrodes in the display device 10 according to an embodiment of the present disclosure. The electrode layer 37 may include a metal having conductivity. For example, the electrode layer 37 may include at least one of aluminum (Al), titanium (Ti), indium (In), gold (Au), silver (Ag), indium tin oxide (ITO), indium zinc oxide (IZO), and indium tin-zinc oxide (ITZO). In addition, the electrode layer 37 may include a semiconductor material doped with n-type or p-type impurities. The electrode layer 37 may include the same material or may include different materials. It is, however, to be understood that the present disclosure is not limited thereto.

The insulating film 38 is disposed to surround the outer surfaces of the plurality of semiconductor layers and electrode layers described above. According to an embodiment of the present disclosure, the insulating film 38 may be disposed to surround at least the outer surface of the light-emitting layer 36, and may be extended in a direction in which the light-emitting element 30 is extended. The insulating film 38 may protect the above-described elements. For example, the insulating film 38 may be formed to surround the side surfaces of the elements, and both ends of the light-emitting element 30 in the longitudinal direction may be exposed.

Although the insulating film 38 is extended in the longitudinal direction of the light-emitting element 30 to cover from the first semiconductor layer 31 to the side surface of the electrode layer 37 in the example shown in the drawing, the present disclosure is not limited thereto. For example, the insulating film 38 may cover only the outer surface of a portion of the semiconductor layer, including the light-emitting layer 36, or may cover only a portion of the outer surface of the electrode layer 37 to partially expose the outer surface of the electrode layer 37. In an embodiment, a portion of the upper surface of the insulating film 38 which is adjacent to at least one end of the light-emitting element 30 may be rounded in cross-section.

The thickness of the insulating film 38 may be, but is not limited to, in the range of 10 nm to 1.0 μm. In an embodiment, the thickness of the insulating film 38 may be approximately 40 nm.

The insulating film 38 may include any of materials having an insulating property, such as silicon oxide (SiOx), silicon nitride (SiNx), silicon oxynitride (SiOxNy), aluminum nitride (AlN) and aluminum oxide (Al₂O₃). Accordingly, it is possible to prevent or substantially prevent an electrical short circuit that may occur when the light-emitting layer 36 comes in contact with an electrode through which an electric signal is transmitted to the light-emitting element 30. In addition, since the insulating film 38 includes the light-emitting layer 36 to protect the outer surface of the light-emitting element 30, it is possible to prevent or substantially prevent a decrease in luminous efficiency.

In addition, in some embodiments, the outer surface of the insulating film 38 may be subjected to surface treatment. The light-emitting elements 30 may be dispersed in an ink, and droplets of the ink may be ejected onto the electrode. In doing so, a surface treatment may be applied to the insulating film 38 such that it becomes hydrophobic or hydrophilic in order to keep the light-emitting elements 30 dispersed in the ink from being aggregated with one another.

In an embodiment, a length h of the light-emitting element 30 may be in a range from 1 μm to 10 μm or from 2 μm to 6 μm, and, in an embodiment, approximately 3 μm to 5 μm. In addition, the diameter of the light-emitting elements 30 may be in a range from 30 nm to 700 nm, and an aspect ratio of the light-emitting elements 30 may be in a range from 1.2 to 100. It is, however, to be understood that the present disclosure is not limited thereto. The plurality of light-emitting elements 30 included in the display device 10 may have different diameters depending on compositional difference of the light-emitting layer 36. In an embodiment, the diameter of the light-emitting elements 30 may be approximately 500 nm.

FIG. 9 is a cross-sectional view of a portion of a display device according to an embodiment of the present disclosure.

FIG. 9 is a cross-sectional view passing through first patterns 70 and light-emitting elements 30, showing a structure in which the light-emitting elements 30 are disposed between the first patterns 70, similarly to FIG. 5. The embodiment of FIG. 9 is substantially the same as the above-described embodiment of FIG. 5 except that the cross-sectional shape of the first patterns 70 is different, and, therefore, redundant descriptions will be omitted.

Referring to FIG. 9, unlike FIG. 5 described above, the first patterns 70 may have a rectangular or square cross-sectional shape. An electric field is generated when the light-emitting elements 30 are aligned, which will be described later, and the intensity of the electric field is reduced in proportion to the thickness of the first patterns 70 thereon. When the cross-sectional shape of the first patterns 70 is formed in a rectangular or square shape, the height of the first patterns 70 in the vertical direction may be uniform or substantially uniform across different positions. That is, as the cross-sectional shape of the first patterns 70 is formed in a rectangle or a square, the intensity of the electric field generated over the first pattern 70 can be made uniform or substantially uniform, such that it is possible to guide the light-emitting elements 30 so as to be seated between the first patterns 70 and not on the first patterns 70.

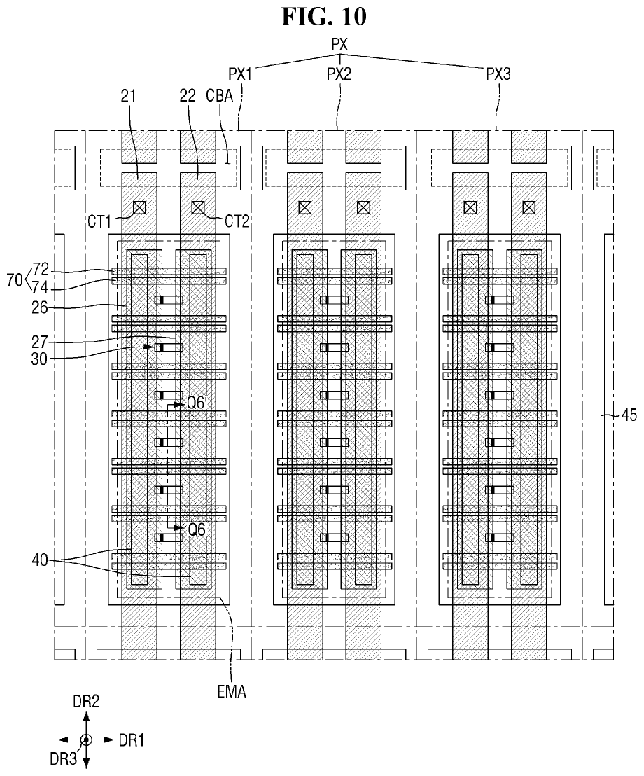

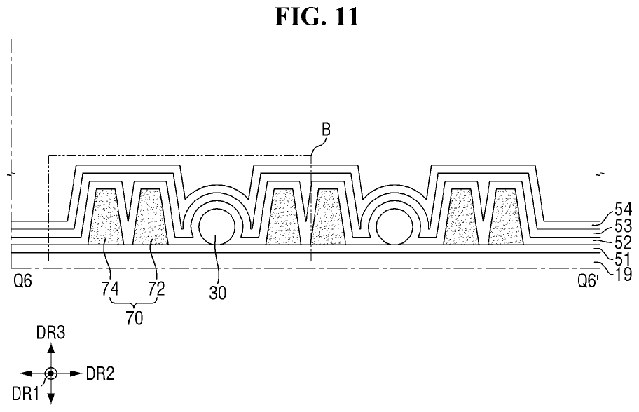

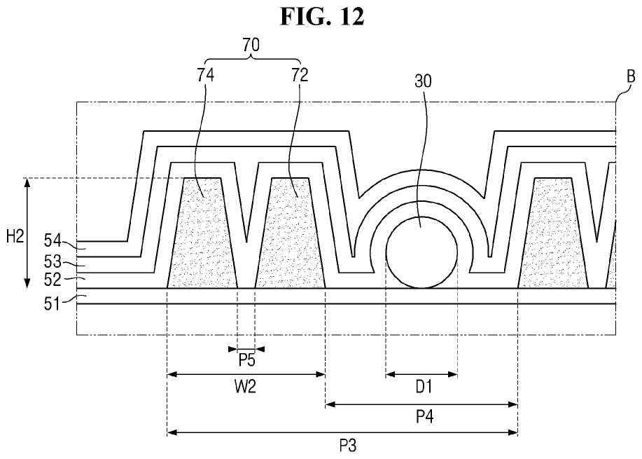

FIG. 10 is a plan view showing a pixel of a display device according to an embodiment of the present disclosure. FIG. 11 is a cross-sectional view taken along the line Q6-Q6′ of FIG. 10. FIG. 12 is an enlarged view of a region “B” of FIG. 11.

The embodiment of FIGS. 10 to 12 is substantially the same as the above-described embodiment of FIGS. 2 to 7 except that each of first patterns 70 is divided into a plurality of sub-patterns, and, therefore, redundant descriptions will be omitted.

Referring to FIGS. 10 to 12, a first pattern 70 according to an embodiment may include a first sub-pattern 72 and a second sub-pattern 74. The first sub-pattern 72 and the second sub-pattern 74 may be disposed on the first insulating layer 51. The first sub-pattern 72 and the second sub-pattern 74 may have a thickness smaller than that of the second bank 45 and may be spaced apart from each other in the second direction DR2. The first sub-pattern 72 and the second sub-pattern 74 may be spaced apart from the second bank 45. In an embodiment, each of the first sub-pattern 72 and the second sub-pattern 74 may have a trapezoidal cross section. The cross-sectional shape of the first sub-pattern 72 and the second sub-pattern 74 may be similar to one obtained by patterning an organic material. It is, however, to be understood that the present disclosure is not limited thereto.

According to an embodiment of the present disclosure, the first patterns 70 including the first sub-patterns 72 and the second sub-patterns 74 may guide the light-emitting elements 30 so as to be located at intended positions in the emission area EMA of each sub-pixel PXn, similar to the first banks 40, such that a large number of light-emitting elements 30 can be disposed between the first banks 40. The first sub-pattern 72 and the second sub-pattern 74 may be formed by dividing each of the first patterns 70 shown in FIGS. 2 to 7 into two.

The first sub-pattern 72 and the second sub-pattern 74 may have such a thickness that the light-emitting elements 30 can be guided therebetween due to the level differences. According to an embodiment of the present disclosure, a height of each of the first sub-pattern 72 and the second sub-pattern 74 may be equal to the height of the first pattern 70 shown in FIGS. 2 to 7 described above. It is, however, to be understood that the present disclosure is not limited thereto. In an embodiment, the first sub-pattern 72 and the second sub-pattern 74 may have different heights.

In an embodiment, a height H2 of each of the first sub-pattern 72 and the second sub-pattern 74 may be larger than the diameter D1 of the light-emitting elements 30. As the height H2 of the first sub-pattern 72 and the second sub-pattern 74 is greater than the diameter D1 of the light-emitting elements 30, the intensity of the electric field generated over the first sub-pattern 72 and the second sub-pattern 74 may become larger than that over the first insulating layer 51 where the light-emitting elements 30 are seated between the first patterns 70. As a result, the light-emitting elements 30 may be moved to the side where the intensity of the electric field is greater, and thus may be aligned between the electrodes 21 and 22. According to an embodiment of the present disclosure, the height H2 of each of the first sub-pattern 72 and the second sub-pattern 74 may be greater than the diameter D1 of the light-emitting elements 30, for example, greater than 0.5 μm. In addition, the height H2 of each of the first sub-pattern 72 and the second sub-pattern 74 may be smaller than the height of the second bank 45. The ink in which the light-emitting elements are dispersed may be ejected onto the first patterns 70 including the first sub-patterns 72 and the second sub-patterns 74 to evenly spread within the area partitioned by the second bank 45. As the height H2 of each of the first sub-pattern 72 and the second sub-pattern 74 is smaller than the second bank 45, the ink can spread evenly.

In addition, a pitch P3 of the first patterns 70 including the first sub-pattern 72 and the second sub-pattern 74 may be made larger than a distance P4 between the first patterns 70. In an embodiment, the pitch P3 of the first patterns 70 including the first sub-patterns 72 and the second sub-patterns 74 may be equal to or less than 5 μm. The light-emitting elements 30 may be aligned so as to be spaced apart from one another by a certain distance by repulsive force acting on each other. In an embodiment, the distance between the light-emitting elements 30 spaced apart from one another due to the repulsive force may be approximately 5 μm. When the pitch P3 of the first patterns 70 is greater than 5 μm, it is possible to prevent a number of light-emitting elements 30 disposed between the first patterns 70 from sticking together and creating a short circuit. According to an embodiment of the present disclosure, the distance P4 between the first patterns 70 including the first sub-patterns 72 and the second sub-patterns 74 may be greater than 0.5 μm and less than 4 μm.

In addition, according to an embodiment of the present disclosure, a width W2 of the first patterns 70 including the first sub-patterns 72 and the second sub-patterns 74 may be equal to the sum of the widths of the first sub-pattern 72 and the second sub-pattern 74 and a distance P5 between the first sub-pattern 72 and the second sub-pattern 74. The width of each of the first sub-pattern 72 and the second sub-pattern 74 may be smaller than that of the first pattern 70 including the first sub-pattern 72 and the second sub-pattern 74, such that the first sub-pattern 72 and the second sub-pattern 74 may be spaced apart from each other. Accordingly, the sum of the widths of the first sub-pattern 72 and the second sub-pattern 74 may be smaller than the width of the first pattern 70 due to the distance P5 between the first sub-pattern 72 and the second sub-pattern 74. According to an embodiment of the present disclosure, the distance P5 between the first sub-pattern 72 and the second sub-pattern 74 may be smaller than the diameter D1 of the light-emitting element 30 and may be less than 0.5 μm.

The width W2 of the first pattern 70 including the first sub-pattern 72 and the second sub-pattern 74 may be greater than the diameter D1 of the light-emitting element 30 and may be smaller than the pitch P3 of the first patterns 70. According to an embodiment of the present disclosure, since the pitch P3 of the first patterns 70 including the first sub-patterns 72 and the second sub-patterns 74 is less than 5 μm and the distance P4 between the first patterns 70 is greater than 0.5 μm and less than 4 μm, the width W2 of the first patterns 70 may be greater than 1 μm and less than 4.5 μm. When the width W2 of the first patterns 70 is greater than 1 μm, the light-emitting elements 30 can be rotated and aligned within the distance P4 between the first patterns 70, and when the width W2 of the first patterns 70 is less than 4.5 μm, the light-emitting elements 30 can be well seated within the distance P4 between the first patterns 70.

It is to be noted that the width W2 and the height H2 of the first patterns 70 including the first sub-patterns 72 and the second sub-patterns 74 are not limited to those described above but may be adjusted as the diameter D1 and/or length of the light-emitting elements 30 is changed.

The display device 10 according to an embodiment may include the first patterns 70 including the first sub-patterns 72 and the second sub-patterns 74 arranged in a direction between the second banks 45. Even though the first patterns 70 are divided into the first sub-patterns 72 and the second sub-patterns 74, the distance between the first sub-pattern 72 and the second sub-pattern 74 is narrow. Accordingly, the intensity of the electric field generated over the first sub-pattern 72 and the second sub-pattern 74 can be reduced. Accordingly, the display device 10 can guide most of the light-emitting elements 30 to be aligned between the first patterns 70 during the fabricating process, and a number of the light-emitting elements 30 lost in each sub-pixel PXn can be reduced.

Although the first patterns 70 are divided into two sub-patterns 72 and 74 in the example shown in FIGS. 10 to 12, the present disclosure is not limited thereto. For example, the first patterns 70 may be divided into three or more sub-patterns as long as the width is substantially equal to the width of the first patterns 70 of FIGS. 2 to 7, which are not divided into sub-patterns.

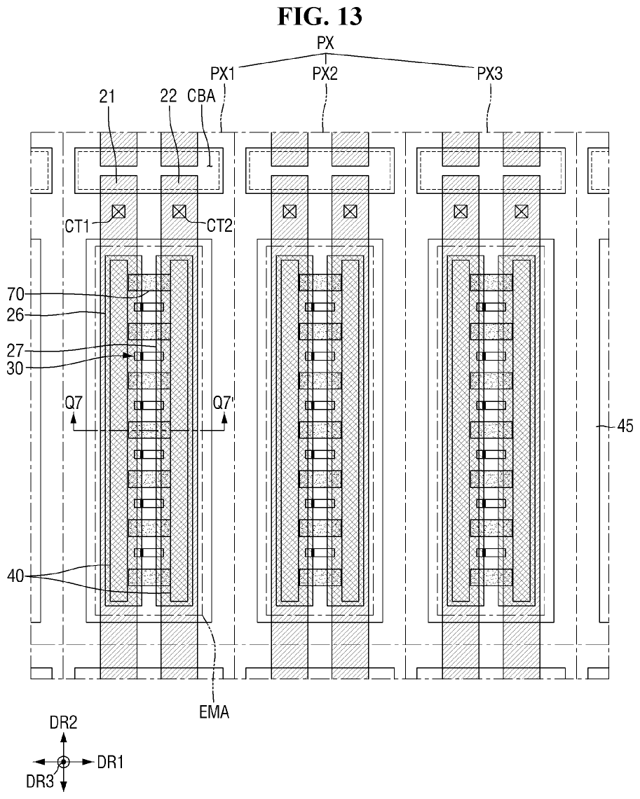

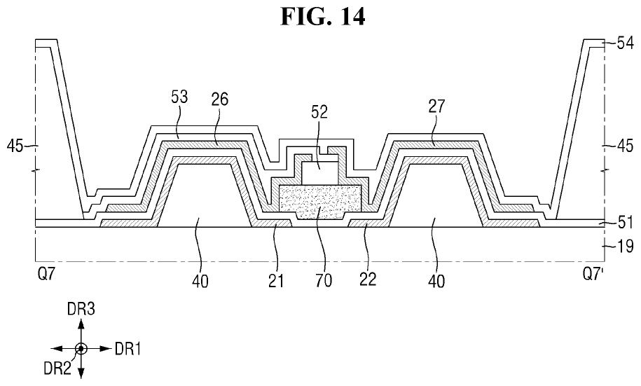

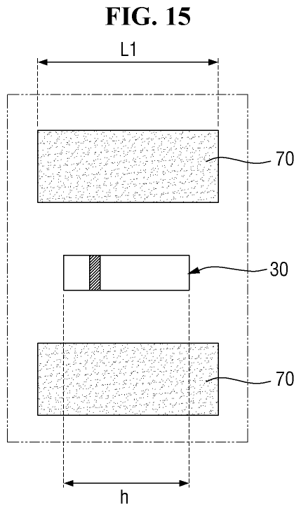

FIG. 13 is a plan view showing a pixel of a display device according to another embodiment of the present disclosure. FIG. 14 is a cross-sectional view taken along the line Q7-Q7′ of FIG. 13. FIG. 15 is a view showing first patterns and a light-emitting element of FIG. 13.

The embodiment of FIGS. 13 to 15 is substantially the same as the above-described embodiment of FIGS. 2 to 7 except that first patterns 70 are disposed between first banks 40, and, therefore, redundant descriptions will be omitted.

Referring to FIGS. 13 to 15, a display device 10 may include a plurality of first patterns 70 disposed between first banks 40. The plurality of first patterns 70 may be spaced apart from one another in the second direction DR2 between the first banks 40. In addition, the width of the first patterns 70 may be smaller than the distance between the first banks 40 and may be spaced apart from the first banks 40. The first patterns 70 may not overlap with the first banks 40.

The light-emitting elements 30 disposed in an ink may be ejected onto the electrodes 21 and 22 to be described later, and may be arranged thereon by an electric field generated over the electrodes 21 and 22. The intensity of the electric field substantially generated by the first banks 40 may be the greatest between the first banks 40. The light-emitting elements 30 are guided toward an area where the intensity of the electric field is greater. Accordingly, in an embodiment, the first patterns 70 may be arranged between the first banks 40 to guide the alignment of the light-emitting elements 30.

In an embodiment, a length L1 of the first patterns 70 in the second direction DR2 may be greater than the width of the second insulating layer 52 disposed on the first patterns 70 in the second direction. In addition, the length L1 of the first patterns 70 in the second direction DR2 may be larger than the length h of the light-emitting elements 30. As the length L1 of the first patterns 70 in the second direction DR2 is greater than the length h of the light-emitting elements 30, the light-emitting elements 30 can be easily aligned in the second direction DR2 between the first banks 40. That is, it is possible to prevent or substantially prevent that the light-emitting elements 30 are not aligned in the second direction DR2 but are obliquely aligned.

According to an embodiment of the present disclosure, the display device 10 may include a plurality of first patterns 70 arranged in a direction between the first banks 40. The display device 10 can guide the light-emitting elements 30 such that most of the light-emitting elements 30 are aligned at intended positions during the fabricating process, and can reduce a number of the light-emitting elements 30 lost in each sub-pixel PXn.

Herein, processing steps, or tasks, of fabricating the display device 10 according to an embodiment of the present disclosure will be described with reference to other drawings. Herein, a method of fabricating the display device according to the embodiment shown in FIGS. 2 to 7 will be described as an example.

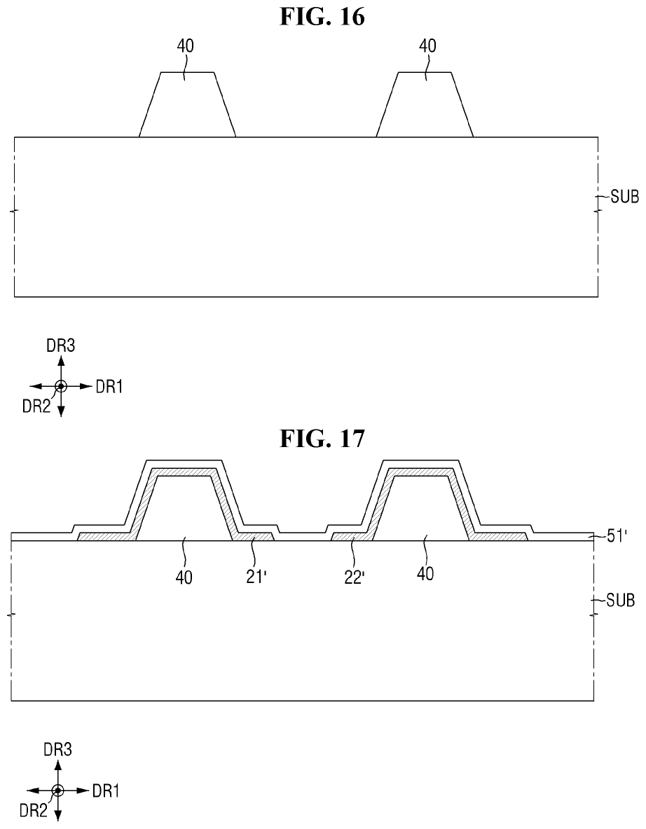

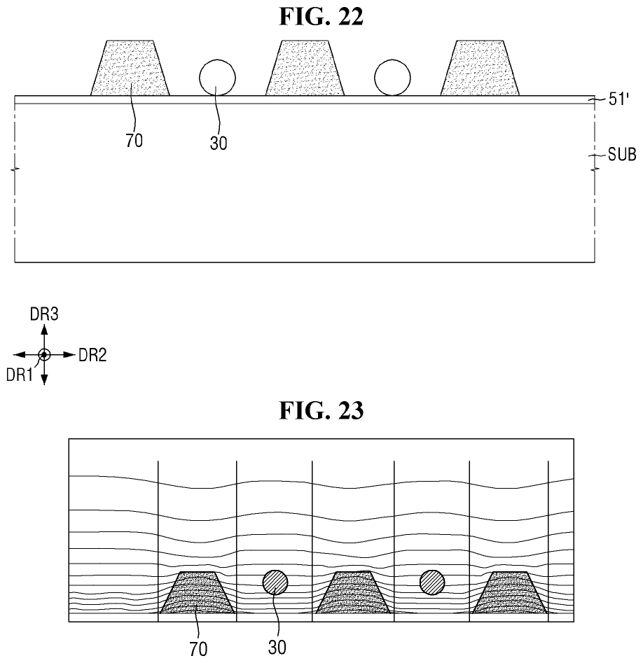

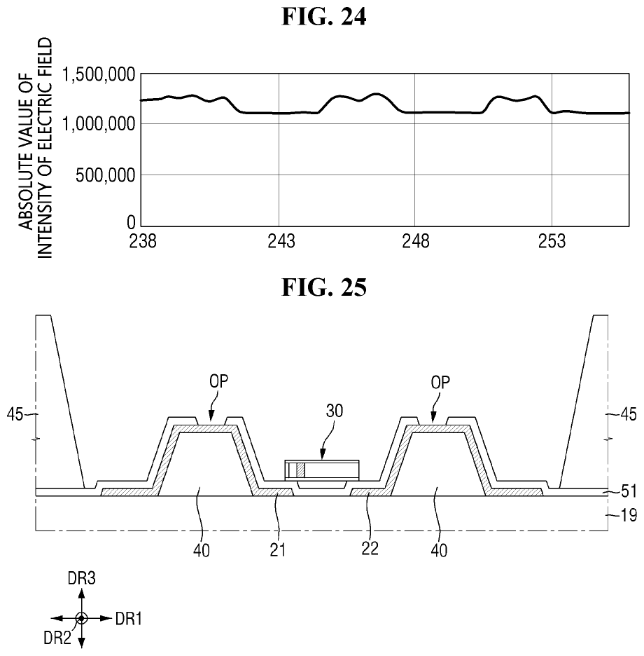

FIGS. 16 to 22, 25, and 26 are cross-sectional views showing some of processing steps of fabricating a display device according to an embodiment of the present disclosure. FIG. 23 is a view schematically showing a distribution of intensity of an electric field. FIG. 24 is a graph showing the absolute value of the intensity of the electric field.

Referring first to FIG. 16, a target substrate SUB is prepared. Although not shown in the drawings, the target substrate SUB may include the above-described first substrate 11, and may include circuit elements consisting of a plurality of conductive layers and a plurality of insulating layers. In the following description, the target substrate SUB including such elements and layers will be described for convenience of illustration.

Subsequently, a plurality of first banks 40 spaced apart from one another is formed on the target substrate SUB. The first banks 40 may have a shape protruding from the upper surface of the target substrate SUB. A description thereof has already been provided above.

Subsequently, referring to FIG. 17, a first electrode layer 21′ and a second electrode layer 22′ are formed on the first banks 40 on the target substrate SUB. The first electrode layer 21′ and the second electrode layer 22′ are extended in the second direction DR2 and are spaced apart from each other in the first direction DR1. The first electrode layer 21′ and the second electrode layer 22′ may be extended in the second direction DR2 during the processing steps of fabricating the display device 10 and may be disposed in other sub-pixels PXn. After the light-emitting elements 30 are disposed during a subsequent process, the first electrode layer 21′ and the second electrode layer 22′ are separated at the cut area CBA of each of the sub-pixels PXn, such that the first electrode 21 and the second electrode 22 may be formed.

Subsequently, a first insulating material layer 51′ covering the first electrode layer 21′ and the second electrode layer 22′ is formed. In an embodiment, the first insulating material layer 51′ may be disposed on the entire target substrate SUB and may cover the electrode layers 21′ and 22′. The first insulating material layer 51′ may be partially removed during a subsequent process to expose upper surfaces of the electrode layers 21′ and 22′, such that the first insulating layer 51 may be formed.

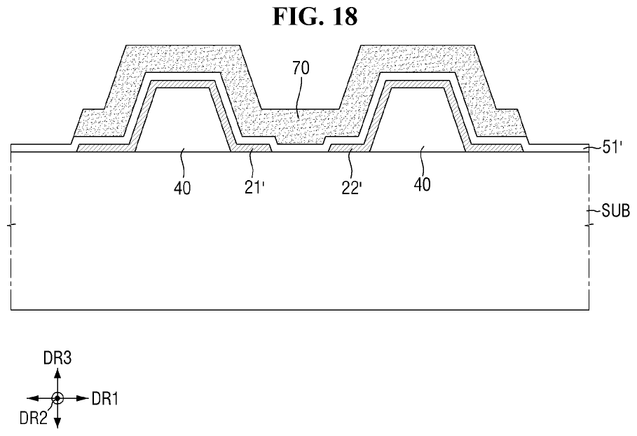

Subsequently, referring to FIG. 18, a plurality of first patterns 70 is formed. The first patterns 70 may be extended in the first direction DR1 and may be spaced apart from each other in the second direction DR2. The first patterns 70 may be spaced apart from each other in the second direction DR2 between the first banks 40 or between the first electrode layer 21′ and the second electrode layer 22′. Areas where the first patterns 70 are disposed and areas where the first patterns 70 are not disposed may be formed between the first banks 40. The areas may have different heights. The first patterns 70 may be formed on the first insulating material layer 51′ and may cover the first banks 40 and the first and second electrode layers 21′ and 22′.

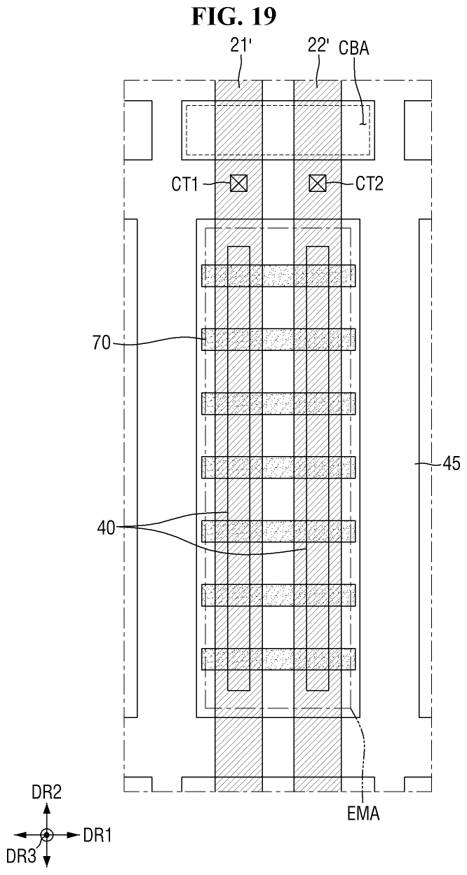

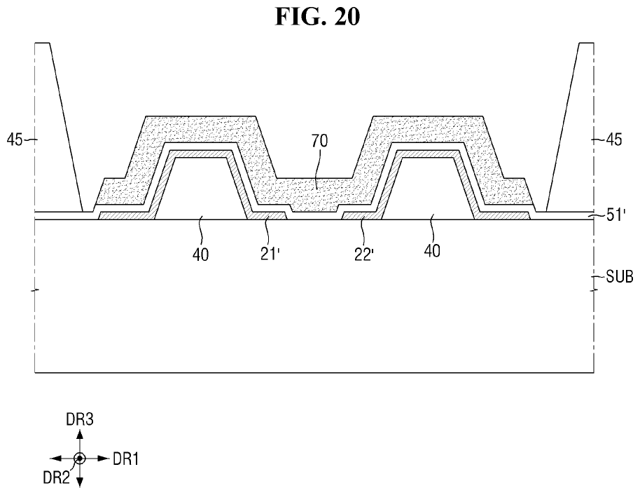

Referring to FIGS. 19 and 20, a second bank 45 is formed on the first insulating material layer 51′ to surround an emission area EMA and a cut area CBA of each sub-pixel PXn. The second bank 45 is disposed to surround each of the sub-pixels PXn to distinguish them from one another, and also to distinguish the emission area EMA from the cut area CBA. A description thereof has already been provided above.

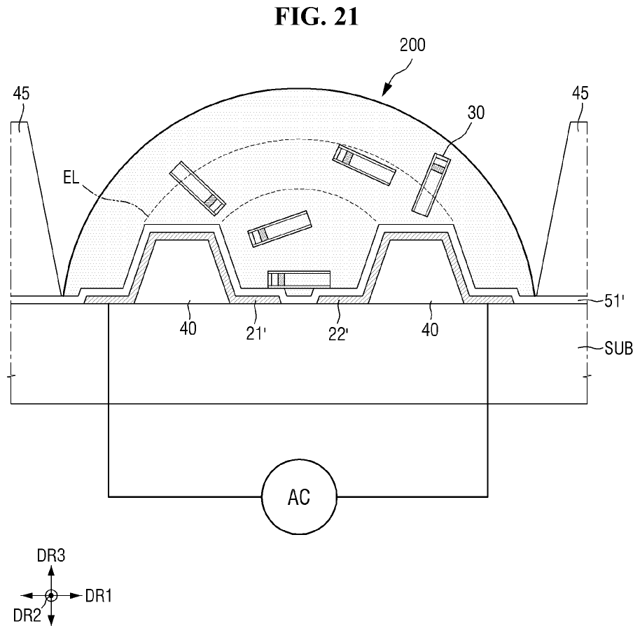

FIG. 21 is a cross-sectional view showing an area in which the first patterns 70 are not disposed but the light-emitting elements 30 are disposed between the second banks 45. FIG. 22 is a view showing a cross-section passing through the first patterns 70 and the light-emitting elements 30.

Referring to FIG. 21, a plurality of light-emitting elements 30 is disposed between the first banks 40. The light-emitting elements 30 may be disposed on the first insulating material layer 51′ such that opposite ends of the light-emitting elements 30 are disposed on the first electrode layer 21′ and the second electrode layer 22′, respectively. The light-emitting elements 30 may be dispersed in an ink 200 and may be ejected onto the target substrate SUB. In an embodiment, the light-emitting elements 30 may be prepared as they are dispersed in the ink 200 containing a solvent and may be sprayed onto the target substrate SUB via a printing process using an inkjet printing apparatus. The ink ejected from the inkjet printing apparatus may be settled in the area surrounded by the second bank 45. The second bank 45 can prevent or substantially prevent the ink from overflowing to other neighboring sub-pixels PXn.

When the ink 200 containing the light-emitting elements 30 is ejected, an electrical signal is applied to the electrode layers 21′ and 22′ such that a plurality of light-emitting elements 30 is disposed on the first insulating material layer 51′. When the electrical signal is applied to the electrode layers 21′ and 22′, an electric field may be generated over the electrode layers 21′ and 22′. The light-emitting elements 30 dispersed in the ink 200 may be subjected to a dielectrophoresis force by the electric field, and, thus, the light-emitting elements 30 subjected to the dielectrophoresis force may be seated on the first insulating material layer 51′ while orientations and positions thereof are changed.

Referring to FIG. 22, the light-emitting elements 30 may be disposed between the first patterns 70. The first patterns 70 can guide the light-emitting elements 30 to a position such that the opposite ends of the light-emitting elements 30 can be placed on the electrode layers 21′ and 22′, respectively, and most of the light-emitting elements 30 can be disposed at a lower position due to the level differences formed by the first patterns 70.

FIG. 23 shows the distribution of electric field generated in the structure shown in FIG. 22. FIG. 24 shows the absolute value of the intensity of the electric field generated in the structure shown in FIG. 22. FIGS. 23 and 24 may directly correspond to the structure of FIG. 22.

Referring to FIGS. 23 and 24, when an electric field is generated after the ink 200 containing the light-emitting elements 30 has been ejected, the intensity of the electric field is weaker at the areas where the first patterns 70 are disposed while the intensity of the electric field is larger in the areas between the first patterns 70. As a result, the light-emitting elements 30 may be guided to and aligned in the areas between the first patterns 70 having a larger intensity of electric field. The light-emitting elements 30 placed on the first patterns 70 are moved to the areas between the first patterns 70 having a larger intensity of the electric field when an electric field is generated. Therefore, the light-emitting elements 30 may not be disposed on the first patterns 70.

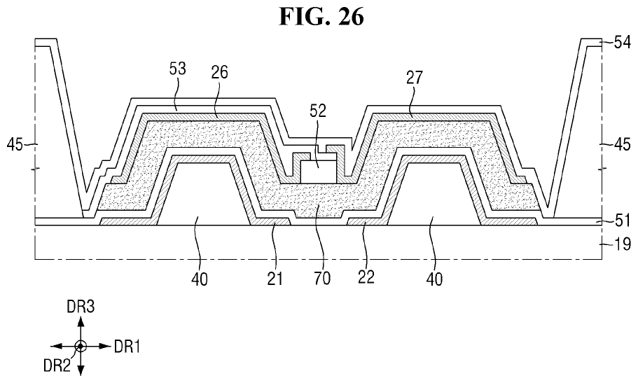

Referring to FIG. 25, after the light-emitting elements 30 have been aligned, a portion of the first insulating material layer 51′ is removed such that the upper surfaces of the first electrode layer 21′ and the second electrode layer 22′ are exposed, thereby forming the first insulating layer 51. The first insulating layer 51 may include an opening OP exposing a portion of the electrode layers 21′ and 22′. The upper surfaces of the electrode layers 21′ and 22′ exposed through the openings OP may be in contact with the contact electrodes 26 and 27 described later.

Subsequently, referring to FIG. 26, a process of cutting portions of the first electrode layer 21′ and the second electrode layer 22′ that are disposed in the cut area CBA (see FIG. 19) is carried out, to form a first electrode 21 and a second electrode 22. Subsequently, a second insulating layer 52, a third insulating layer 53, and contact electrodes 26 and 27 are formed on the light-emitting elements 30. The electrical signal for aligning the light-emitting elements 30 may be applied through the electrode layers 21′ and 22′ connected to the plurality of sub-pixels PXn. It is to be noted that in order to drive the display device 10, the electrode layers 21′ and 22′ may be separated from each other at the cut area CBA to form the electrodes 21 and 22, and each of the electrodes 21 and 22 may be individually driven through a first transistor disposed in each of the sub-pixels PXn.

Subsequently, a fourth insulating layer 54 covering the elements disposed on the target substrate SUB is formed, thereby fabricating the display device 10.

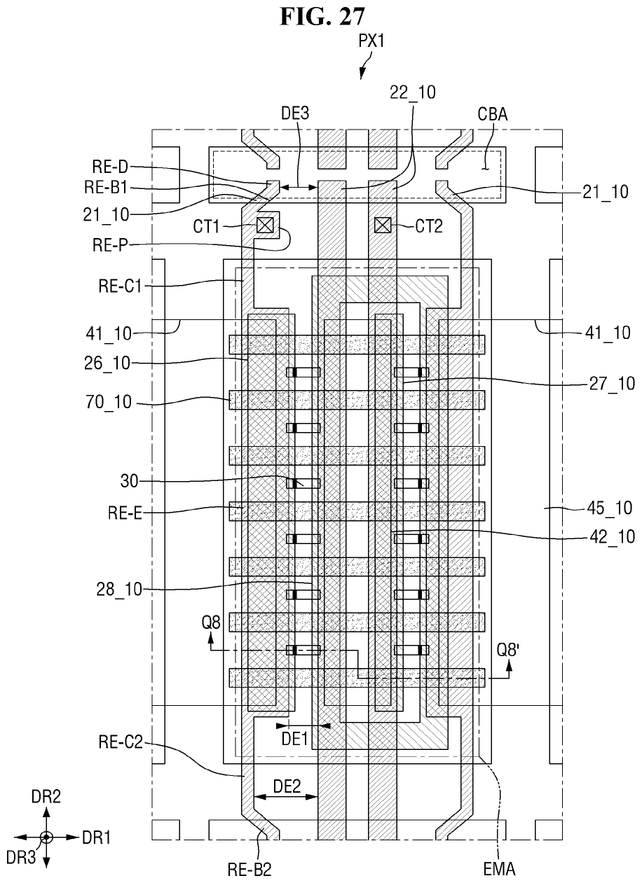

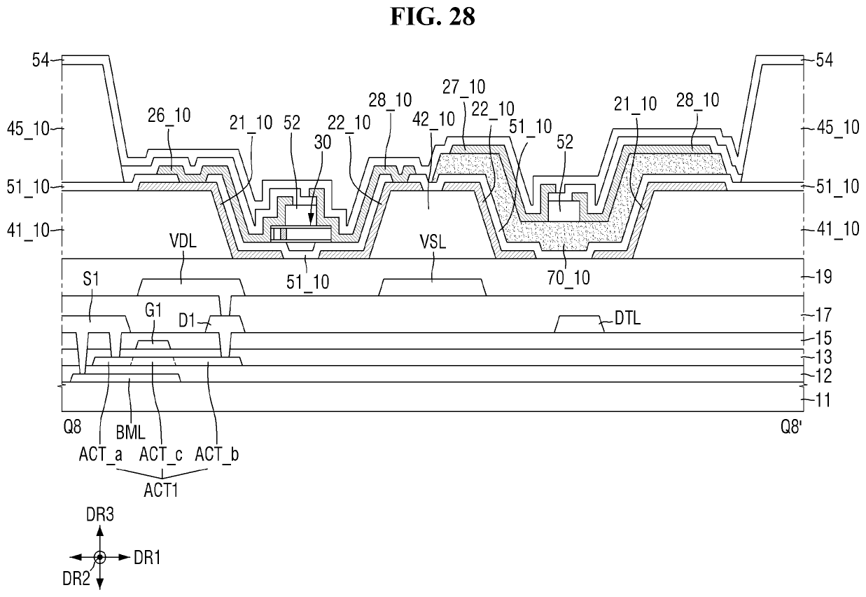

FIG. 27 is a plan view showing a sub-pixel of a display device according to an embodiment of the present disclosure. FIG. 28 is a cross-sectional view taken along the line Q8-Q8′ of FIG. 27.

Referring to FIGS. 27 and 28, a display device may include a plurality of first electrodes 21_10 and a plurality of second electrodes 22_10 in each of the sub-pixels PXn. The first electrodes 21_10, for example, two first electrodes 21_10, may be disposed symmetrically with respect to the center of the sub-pixel PXn. The second electrodes 22_10 may have the same shape as in the embodiment of FIG. 2, and a plurality of second electrodes 22_10, e.g., two second electrodes 22_10, may be disposed between the first electrodes 21_10. A distance between the first electrode 21_10 and the second electrodes 22_10 may vary along the first electrodes 21_10. For example, a distance DE1 between an expanded portion RE-E and the second electrode 22_10 may be smaller than a distance DE2 between connection portions RE-C1 and RE-C2 and the second electrode 22_10 and a distance DE3 between bent portions RE-B1 and RE-B2 and the second electrode 22_10. The distance DE2 between the connection portions RE-C1 and RE-C2 and the second electrode 22_10 may be larger than the distance DE3 between the bent portions RE-B1 and RE-B2 and the second electrode 22_10. It is, however, to be understood that the present disclosure is not limited thereto. The shape of each of the electrodes 21_10 and 22_10 may be the same or substantially the same as that described above with reference to FIG. 2, and, therefore, redundant descriptions will be omitted.

The arrangements and shapes of first sub-banks 41_10, 42_10, a first insulating layer 51_10 and contact electrodes 26_10, 27_10, and 28_10 disposed in each sub-pixel PXn may be changed depending on the arrangement of the first electrodes 21_10 and the second electrodes 22_10.

The first insulating layer 51_10 is disposed between the expanded portion RE-E of the first electrode 21_10 and the second electrode 22_10, and both side surfaces thereof may be in contact with the first electrode 21_10 and the second electrode 22_10, respectively. The first end of the light-emitting element 30 may be disposed on the expanded portion RE-E of the first electrode 21_10, and the second end thereof may be disposed on the second electrode 22_10.

The first bank 40 may include a first sub-bank 41_10 and a second sub-bank 42_10 having different widths. The first sub-bank 41_10 and the second sub-bank 42_10 may be extended in the second direction DR2 and may have different widths measured in the first direction DR1. As the first sub-bank 41_10 has a larger width than the second sub-bank 42_10, it may be disposed across the boundary of the adjacent sub-pixel PXn in the first direction DR1. For example, the first sub-bank 41_10 may be disposed at the boundary between the emission areas EMA, including the emission areas EMA of the sub-pixels PXn. Accordingly, parts of the portions of a second bank 45_10 extended in the second direction DR2 may be disposed on the first sub-bank 41_10. Two first sub-banks 41_10 may be partially disposed in one sub-pixel PXn. One second sub-bank 42_10 may be disposed between the first sub-banks 41_10.

The second sub-bank 42_10 may be extended in the second direction DR2 from the center of the emission area EMA of the sub-pixel PXn. In an embodiment, the second sub-bank 42_10 may have a width smaller than that of the first sub-bank 41_10 and may be disposed therebetween such that it is spaced apart therefrom.

The expanded portions RE-E of the first electrode 21_10 and a second bank 45_10 may be disposed on the first sub-banks 41_10. The expanded portions RE-E of the first electrode 21_10 of the sub-pixels PXn adjacent in the first direction DR1 may be disposed on the first sub-bank 41_10. That is, the expanded portions RE-E of the two first electrodes 21_10 are disposed on one first sub-bank 41_10. Two second electrodes 22_10 may be disposed on the second sub-bank 42_10. The second electrodes 22_10 may be disposed on both sides of the second sub-bank 42_10 in the second direction DR2 and may be spaced apart from each other on the second sub-bank 42_10.

One of the first electrodes 21_10 may include a contact portion RE-P to form a first contact hole CT1, while another one of the first electrode 21_10 may not have a contact portion RE-P. Similarly, one of the second electrodes 22_10 may include a contact portion RE-P to form a second contact hole CT2, and another electrode 22_10 may not have a contact portion RE-P. The electrodes 21_10 and 22_10 connected to the first transistor TR1 or the second voltage line VL2 through the contact holes CT1 and CT2 may receive electrical signals therefrom, and other electrodes 21_10 and 22_10 may receive electrical signals through contact electrodes 26_10, 27_10, and 28_10 to be described later.

The light-emitting elements 30 may be disposed on the first insulating layer 51_10 such that opposite ends thereof are placed on the expanded portion RE-E of the first electrode layer 21_10 and the second electrode layer 22_10, respectively. One end of the opposite ends of the light-emitting element 30 where the second semiconductor layer 32 (see FIG. 8) is located may be disposed on the first electrode 21_10. Accordingly, the first ends of the light-emitting elements 30 between the electrodes 21_10 and 22_10 disposed on the left side of the center of the sub-pixel PXn and the first ends of the light-emitting elements 30 between the electrodes 21_10 and 22_10 disposed on the right side of the center of the sub-pixel PXn may face opposite directions.

As the display device includes a larger number of electrodes 21_10 and 22_10, it may include a larger number of contact electrodes 26_10, 27_10, and 28_10.

According to an embodiment of the present disclosure, the contact electrodes 26_10, 27_10, and 28_10 may include a first contact electrode 26_10 disposed on one of the first electrodes 21_10, a second contact electrode 27_10 disposed on one of the second electrodes 22_10, and a third contact electrode 28_10 disposed on another one of the first electrode 21_10 and another one of the second electrode 22_10 and surrounding the second contact electrode 27_10. The first contact electrode 26_10 is disposed on one of the first electrodes 21_10. For example, the first contact electrode 26_10 is disposed on the expanded portion RE-E of the first electrode 21_10 on which the first ends of the light-emitting elements 30 are disposed. The first contact electrode 26_10 may be in contact with the expanded portion RE-E of the first electrode 21_10 and with the first ends of the light-emitting elements 30. The second contact electrode 27_10 is disposed on one of the second electrodes 22_10. For example, the second contact electrode 27_10 is disposed on the second electrode 22_10 on which the second ends of the light-emitting elements 30 are disposed. The second contact electrode 27_10 may be in contact with the second electrode 22_10 and the second ends of the light-emitting elements 30.

The first contact electrode 26_10 and the second contact electrode 27_10 may be in contact with the electrodes 21_10 and 22_10 in which the first contact hole CT1 and the second contact hole CT2 are formed, respectively. The first contact electrode 26_10 may be in contact with the first electrode 21_10 electrically connected to the first transistor TR1 through the first contact hole CT1, and the second contact electrode 27_10 may be in contact with the second electrode 22_10 electrically connected to the second voltage line VL2 through the second contact hole CT2. The first contact electrode 26_10 and the second contact electrode 27_10 may transmit electric signals applied from the first transistor TR1 or the second voltage line VL2 to the light-emitting elements 30. The first contact electrode 26_10 and the second contact electrode 27_10 may be substantially the same as those described above.

The electrodes 21_10 and 22_10 in which the contact holes CT1 and CT2 are not formed are further disposed in each sub-pixel PXn. These may be substantially floating, i.e., no electric signal is directly applied thereto from the first transistor TR1 or the second voltage line VL2. The third contact electrode 28_10 may be disposed above the electrodes 21_10 and 22_10 on which the contact holes CT1 and CT2 are not formed, and the electric signals transmitted to the light-emitting elements 30 may flow through the third contact electrode 28_10.

The third contact electrode 28_10 may be disposed on the first electrode 21_10 and the second electrode 22_10 where the contact holes CT1 and CT2 are not formed, and may be disposed to surround the second contact electrode 27_10. The third contact electrode 28_10 may include portions extended in the second direction DR2 and portions extended in the first direction DR1 to connect them, and may surround the second contact electrode 27_10. The portions of the third contact electrode 28_10 extended in the second direction DR2 may be disposed on the first electrode 21_10 and the second electrode 22_10 where the contact holes CT1 and CT2 are not formed, respectively, and may be in contact with the light-emitting elements 30. For example, a portion of the third contact electrode 28_10 disposed on the second electrode 22_10 may be in contact with the second ends of the light-emitting elements 30 on the left side, and a portion of the third contact electrode 28_10 disposed on the first electrode 21_10 may be in contact with first ends of the light-emitting element 30 on the right side. The portions of the third contact electrode 28_10 extended in the first direction DR1 may overlap the second electrode 22_10 where the second contact hole CT2 is formed, but there may be another insulating layer (not shown) therebetween such that they may not be directly connected to each other.

The electric signal transmitted from the first contact electrode 26_10 to the first ends of the light-emitting elements 30 on the left side is transmitted to the third contact electrode 28_10 in contact with the second ends of the light-emitting elements 30 on the left side. The third contact electrode 28_10 may transmit the electric signal to the first ends of the light-emitting elements 30 on the right side, which may be transmitted to the second electrode 22_10 through the second contact electrode 27_10. In this manner, the electric signal for light emission of the light-emitting elements 30 can be transmitted to only one first electrode 21_10 and one second electrode 22_10, and the light-emitting elements 30 disposed on the left side and the light-emitting elements 30 disposed on the right side may be connected in series through the third contact electrode 28_10.

According to an embodiment of the present disclosure, first patterns 70_10 may be extended in the first direction DR1 on the first insulating layer 51_10 and may be spaced apart from each other in the second direction DR2. One light-emitting element 30 may be disposed and aligned between every two of the first patterns 70_10. As the display device 10 includes the first patterns 70_10, the display device 10 can guide most of the light-emitting elements 30 to be aligned at intended positions during the fabricating process, and the number of the light-emitting elements 30 lost in each sub-pixel PXn can be reduced.

In concluding the detailed description, those skilled in the art will appreciate that many variations and modifications can be made to the described embodiments without substantially departing from the principles of the present invention. Therefore, the disclosed embodiments of the invention are used in a generic and descriptive sense and not for purposes of limitation.

What is claimed is:

1. A display device comprising:
a plurality of first banks extended in a first direction on a first substrate and spaced apart from one another;
a first electrode and a second electrode extended in the first direction and located on different ones of the first banks so as to be spaced apart from one another;
a first insulating layer covering the first electrode, the second electrode, and the plurality of first banks;
a plurality of first patterns extended in a second direction crossing the first direction on the first insulating layer and spaced apart from one another; and
a plurality of light-emitting elements between adjacent ones of the first patterns, wherein opposite ends of the light-emitting elements are arranged on the first electrode and the second electrode, respectively, on the first insulating layer,
wherein a height of the first patterns is greater than a diameter of the light-emitting elements.

2. The display device of claim 1, wherein the first patterns overlap the first banks and intersect the first banks perpendicularly.

3. The display device of claim 1, wherein one light-emitting element of the plurality of light-emitting elements is arranged between every two of the first patterns, and
wherein a longitudinal direction of the light-emitting element is parallel to a direction in which the first patterns are extended.

4. The display device of claim 1, wherein a pitch of the first patterns is greater than a distance between the first patterns.

5. The display device of claim 4, wherein the distance between the first patterns is greater than 0.5 μm and less than 4 μm.

6. The display device of claim 1, wherein a width of the first patterns is greater than 1 μm and less than 4.5 μm.

7. The display device of claim 1, wherein a cross-section of the first patterns is any of a trapezoid, a square, and a rectangle.

8. The display device of claim 1, further comprising a second bank surrounding the plurality of light-emitting elements, the first electrode, the second electrode, and the plurality of first banks, and defining an emission area.

9. The display device of claim 8, wherein the first patterns do not overlap with the second bank.

10. The display device of claim 8, wherein a height of the first patterns is greater than 0.5 μm and less than a height of the second bank.

11. The display device of claim 1, wherein the first patterns comprise a first sub-pattern and a second sub-pattern that are extended in the second direction and spaced apart from each other in the first direction.

12. The display device of claim 11, wherein a distance between the first sub-pattern and the second sub-pattern is smaller than the diameter of the light-emitting elements.

13. The display device of claim 1, wherein the first patterns are located between the plurality of first banks and do not overlap with the plurality of first banks.

14. The display device of claim 1, further comprising:
a first contact electrode on the first electrode and in contact with a first end of each of the light-emitting elements; and
a second contact electrode on the second electrode and in contact with a second end of each of the light-emitting elements.

15. A display device comprising:
a plurality of first banks extended in a first direction on a first substrate and spaced apart from one another;
a first electrode and a second electrode extended in the first direction and located on different ones of the first banks so as to be spaced apart from one another;
a first insulating layer covering the first electrode, the second electrode, and the plurality of first banks;
a plurality of first patterns extended in a second direction crossing the first direction on the first insulating layer and spaced apart from one another; and
a plurality of light-emitting elements between adjacent ones of the first patterns, wherein opposite ends of the light-emitting elements are arranged on the first electrode and the second electrode, respectively, on the first insulating layer,
wherein a width of the first patterns is greater than a diameter of the light-emitting elements and less than a pitch of the first patterns.

16. The display device of claim 15, wherein a width of the first patterns is greater than 1 μm and less than 4.5 μm.

17. The display device of claim 15, wherein a pitch of the first patterns is greater than a distance between the first patterns and less than 5 μm.

18. The display device of claim 15, further comprising a second bank surrounding the plurality of light-emitting elements, the first electrode, the second electrode, and the plurality of first banks, and defining an emission area,
wherein the first patterns do not overlap with the second bank.

19. The display device of claim 15, wherein the first patterns comprise a first sub-pattern and a second sub-pattern that are extended in the second direction and spaced apart from each other in the first direction.

20. The display device of claim 15, wherein the first patterns are located between the plurality of first banks and do not overlap with the plurality of first banks.
